(19) United States
(12) Patent Application Publication
(10) Pub. No.: US 2026/0304786 A1
(43) Pub. Date: Oct. 1, 2026

(54) MEMORY DEVICE

(71) Applicant: KIOXIA CORPORATION, Tokyo (JP)

(72) Inventors: Yutaro SHIMODA, Yokkaichi Mie (JP); Katsuyoshi KOMATSU, Yokkaichi Mie (JP); Tadaomi DAIBOU, Yokkaichi Mie (JP); Yosuke MATSUSHIMA, Leuven (BE); Takeshi IWASAKI, Kuwana Mie (JP); Itsuko SAKAI, Seoul Special City (KR); Makoto NAGAMINE, Yokkaichi Mie (JP); Minoru AMANO, Yokkaichi Mie (JP); Akifumi GAWASE, Kuwana Mie (JP); Qi ZHU, Yokkaichi Mie (JP)

(73) Assignee: KIOXIA CORPORATION, Tokyo (JP)

(21) Appl. No.: 19/342,815

(22) Filed: Sep. 29, 2025

(30) Foreign Application Priority Data
Mar. 28, 2025 (JP) 2025-056518

(51) Int. Cl. H10B 63/00; H10B 61/00

(52) U.S. Cl. CPC H10B 63/24; H10B 61/10

(57) ABSTRACT

A memory device of embodiments includes a memory cell including a first electrode, a switching layer, a second electrode, a variable resistance layer, a third electrode, and a switching layer in this order. The switching layer contains an oxide or oxynitride of a first element selected from a group consisting of Al, Si, Ge, Zr, Y, Ta, La, Ce, Ti, Hf, and Mg, a second element different from the first element and selected from a group consisting of Al, Zn, Sn, Ga, Bi, and In, and at a third element selected from a group consisting of Te, S, Se, and Sb. A fourth element selected from a group consisting of Ti, W, Mo, Ta, Al, B, Cr, Hf, Nb, V, Si, and Zr is contained between the first electrode containing carbon or the second electrode containing carbon and the switching layer.

### CROSS-REFERENCE TO RELATED APPLICATION

This application is based upon and claims the benefit of priority from Japanese Patent Application No. 2025-056518, filed on Mar. 28, 2025, the entire contents of which are incorporated herein by reference.

### FIELD

Embodiments described herein relate generally to a memory device.

### BACKGROUND

An example of a large-capacity nonvolatile memory device is a cross-point type two-terminal memory device. In the cross-point type two-terminal memory device, scaling-down and high integration of memory cells are easy.

### BRIEF DESCRIPTION OF THE DRAWINGS

FIG. 1 is a block diagram of a memory device according to a first embodiment;

FIG. 2 is a schematic cross-sectional view of a memory cell in the memory device according to the first embodiment;

FIG. 3 is an explanatory diagram of the function of the memory device according to the first embodiment;

FIG. 4 is an explanatory diagram of the current-voltage characteristics of a switching element in the first embodiment;

FIG. 5 is a schematic cross-sectional view of a memory cell of a memory device according to a comparative example;

FIG. 6 is a schematic cross-sectional view of a memory cell in a memory device according to a first modification example of the first embodiment;

FIG. 7 is a schematic cross-sectional view of a memory cell in a memory device according to a second modification example of the first embodiment;

FIG. 8 is a schematic cross-sectional view of a memory cell in a memory device according to a third modification example of the first embodiment;

FIG. 9 is a schematic cross-sectional view of a memory cell in a memory device according to a second embodiment;

FIG. 10 is a schematic cross-sectional view of a memory cell in a memory device according to a third embodiment;

FIG. 11 is an explanatory diagram of the current-voltage characteristics of a memory element in the third embodiment;

FIG. 12 is an explanatory diagram of a first operation example of a memory operation of the memory device according to the third embodiment;

FIG. 13 is an explanatory diagram of a second operation example of the memory operation of the memory device according to the third embodiment;

FIG. 14 is an explanatory diagram of the current-voltage characteristics of a memory element in a first modification example of the third embodiment;

FIG. 15 is an explanatory diagram of a third operation example of a memory operation of a memory device according to the first modification example of the third embodiment;

FIG. 16 is an explanatory diagram of a fourth operation example of the memory operation of the memory device according to the first modification example of the third embodiment;

FIG. 17 is an explanatory diagram of the current-voltage characteristics of a memory element in a second modification example of the third embodiment;

FIG. 18 is an explanatory diagram of a fifth operation example of a memory operation of a memory device according to the second modification example of the third embodiment;

FIG. 19 is an explanatory diagram of a sixth operation example of the memory operation of the memory device according to the second modification example of the third embodiment;

FIG. 20 is an explanatory diagram of the current-voltage characteristics of a memory element in a third modification example of the third embodiment;

FIG. 21 is an explanatory diagram of a seventh operation example of a memory operation of a memory device according to the third modification example of the third embodiment;

FIG. 22 is an explanatory diagram of an eighth operation example of the memory operation of the memory device according to the third modification example of the third embodiment.

FIG. 23A is a schematic cross-sectional view of a memory cell in a memory device according to a fourth embodiment;

FIG. 23B is a schematic cross-sectional view of a memory cell in a memory device according to other embodiment of the fourth embodiment;

FIG. 24 is a schematic cross-sectional view showing an example of a method for manufacturing the memory device according to the fourth embodiment;

FIG. 25 is a schematic cross-sectional view showing an example of the method for manufacturing the memory device according to the fourth embodiment;

FIG. 26 is a schematic cross-sectional view showing an example of the method for manufacturing the memory device according to the fourth embodiment;

FIG. 27 is a schematic cross-sectional view showing an example of the method for manufacturing the memory device according to the fourth embodiment;

FIG. 28 is a schematic cross-sectional view of a memory cell in a memory device according to a first modification example of the fourth embodiment;

FIG. 29 is a schematic cross-sectional view of a memory cell in a memory device according to a second modification example of the fourth embodiment;

FIG. 30 is a schematic cross-sectional view of a memory cell in a memory device according to a third modification example of the fourth embodiment;

FIG. 31 is a schematic cross-sectional view of a memory cell in a memory device according to a fourth modification example of the fourth embodiment;

FIG. 32 is a schematic cross-sectional view of a memory cell in a memory device according to a fifth modification example of the fourth embodiment;

FIG. 33 is a schematic cross-sectional view of a memory cell in a memory device according to a sixth modification example of the fourth embodiment;

FIG. 34 is a schematic cross-sectional view of a memory cell in a memory device according to a fifth embodiment;

FIG. 35 is a schematic cross-sectional view of a memory cell of a memory device according to a first modification example of the fifth embodiment;

FIG. 36 is a schematic cross-sectional view of a memory cell of a memory device according to a second modification example of the fifth embodiment;

FIG. 37 is a schematic cross-sectional view of a memory cell of a memory device according to a third modification example of the fifth embodiment;

FIG. 38 is a schematic cross-sectional view of a memory cell of a memory device according to a fourth modification example of the fifth embodiment;

FIG. 39 is a schematic cross-sectional view of a memory cell of a memory device according to a fifth modification example of the fifth embodiment;

FIG. 40 is a schematic cross-sectional view of a memory cell of a memory device according to a sixth modification example of the fifth embodiment;

FIG. 41A is a schematic cross-sectional view of a memory cell in a memory device according to a sixth embodiment;

FIG. 41B is a schematic cross-sectional view of a memory cell in a memory device according to a first other embodiment of the sixth embodiment;

FIG. 41C is a schematic cross-sectional view of a memory cell in a memory device according to a second other embodiment of the sixth embodiment;

FIG. 42 is a schematic cross-sectional view of a memory cell in a memory device according to a seventh embodiment; and

FIG. 43 is a schematic cross-sectional view of a memory cell in a memory device according to an eighth embodiment.

### DETAILED DESCRIPTION

A memory device of embodiments includes a memory cell including a first electrode, a second electrode, a third electrode, a switching layer, a variable resistance layer, and a region. The second electrode is provided between the first electrode and the third electrode. The switching layer is provided between the first electrode and the second electrode. The variable resistance layer is provided between the second electrode and the third electrode. The switching layer contains an oxide or oxynitride of a first element being at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg); a second element being different from the first element, and being at least one element selected from a group consisting of aluminum (Al), zinc (Zn), tin (Sn), gallium (Ga), bismuth (Bi), and indium (In); and a third element being at least one element selected from a group consisting of tellurium (Te), sulfur (S), selenium (Se), and antimony (Sb). At least one electrode of the first electrode and the second electrode contains carbon (C). The region is provided between at least one of the at least one electrode and the switching layer, and contains a fourth element, the fourth element being different from the first element, the second element, and the third element, and the fourth element being at least one element selected from a group consisting of titanium (Ti), tungsten (W), molybdenum (Mo), tantalum (Ta), aluminum (Al), boron (B), chromium (Cr), hafnium (Hf), niobium (Nb), vanadium (V), silicon (Si), and zirconium (Zr).

Hereinafter, embodiments will be described with reference to the diagrams. In addition, in the following description, the same or similar members and the like are denoted by the same reference numerals, and the description of the members and the like once described will be omitted as appropriate.

For the qualitative analysis and quantitative analysis of the chemical composition forming the memory device in this specification, for example, Rutherford backscattering spectroscopy (RBS), secondary ion mass spectroscopy (SIMS), energy dispersive X-ray spectroscopy (EDS), and electron energy loss spectroscopy (EELS) can be used. In addition, when measuring the thickness of each member forming the memory device, a distance between members, and the like, for example, a transmission electron microscope (TEM) can be used. In addition, for example, X-ray photoelectron spectroscopy (XPS), X-ray absorption fine structure (XAFS), Raman spectroscopy (Raman), scanning transmission electron microscope (STEM), or EELS can be used to identify the constituent materials of each member forming the memory device, measure the abundance ratio of the constituent materials, identify the bonding state of the constituent materials, identify the local structure (atomic arrangement, atomic distance, and coordination number) of the constituent materials, measure the chemical state of the constituent materials, and compare the concentrations of the constituent materials.

### First Embodiment

A memory device according to a first embodiment includes a memory cell including a first electrode, a second electrode, a third electrode, a switching layer, a variable resistance layer, and a region. The second electrode is provided between the first electrode and the third electrode. The switching layer is provided between the first electrode and the second electrode. The variable resistance layer is provided between the second electrode and the third electrode. The switching layer contains an oxide or oxynitride of a first element being at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg); a second element being different from the first element, and being at least one element selected from a group consisting of aluminum (Al), zinc (Zn), tin (Sn), gallium (Ga), bismuth (Bi), and indium (In); and a third element being at least one element selected from a group consisting of tellurium (Te), sulfur (S), selenium (Se), and antimony (Sb). At least one electrode of the first electrode and the second electrode contains carbon (C). The region is provided between at least one of the at least one electrode and the switching layer, and contains a fourth element, the fourth element being different from the first element, the second element, and the third element, and the fourth element being at least one element selected from a group consisting of titanium (Ti), tungsten (W), molybdenum (Mo), tantalum (Ta), aluminum (Al), boron (B), chromium (Cr), hafnium (Hf), niobium (Nb), vanadium (V), silicon (Si), and zirconium (Zr).

In addition, the memory device according to the first embodiment further includes a plurality of first wirings and a plurality of second wirings crossing the plurality of first wirings. In addition, the memory cell is provided in a portion where one of the plurality of first wirings and one of the plurality of second wirings cross each other.

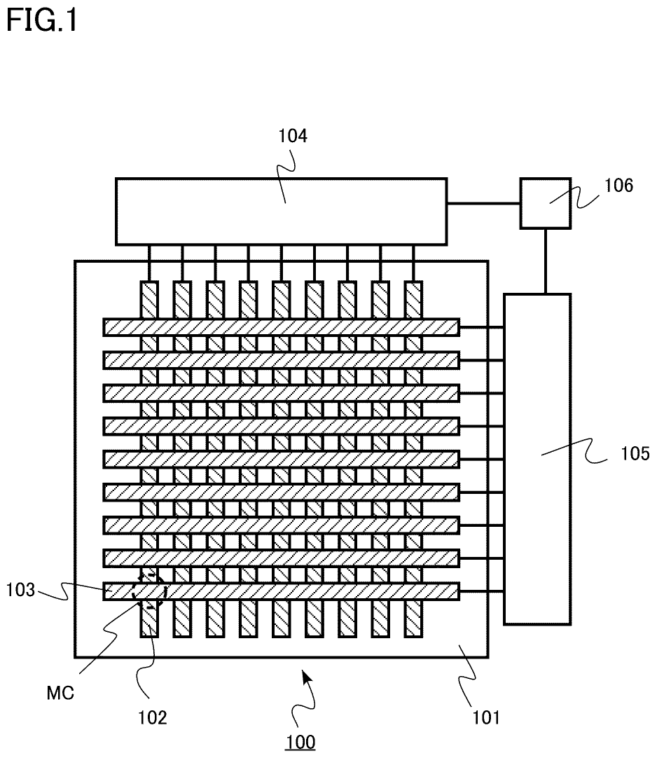

FIG. 1 is a block diagram of the memory device according to the first embodiment.

A memory cell array 100 in the memory device according to the first embodiment includes, for example, a plurality of word lines 102 and a plurality of bit lines 103 crossing the word lines 102 on a semiconductor substrate 101 with an insulating layer interposed therebetween. The bit lines 103 are provided in a layer above the word lines 102, for example. In addition, a first control circuit 104, a second control circuit 105, and a sense circuit 106 are provided as peripheral circuits around the memory cell array 100.

The word line 102 is an example of the first wiring. In addition, the bit line 103 is an example of the second wiring.

A plurality of memory cells MC are provided in portions where the word lines 102 and the bit lines 103 cross each other. The memory device according to the first embodiment is a two-terminal magnetoresistive memory having a cross-point structure.

Each of the plurality of word lines 102 is connected to the first control circuit 104. In addition, each of the plurality of bit lines 103 is connected to the second control circuit 105. The sense circuit 106 is connected to the first control circuit 104 and the second control circuit 105.

The first control circuit 104 and the second control circuit 105 have functions of selecting a desired memory cell MC, writing data to the memory cell MC, reading data from the memory cell MC, and deleting data from the memory cell MC, for example. When reading data, the data in the memory cell MC is read as the amount of current flowing between the word line 102 and the bit line 103 or as an electric potential change of the bit line 103. The sense circuit 106 has a function of determining the amount of current or the electric potential change to determine the polarity of the data. For example, “0” and “1” of data are determined.

The first control circuit 104, the second control circuit 105, and the sense circuit 106 are electronic circuits using semiconductor devices formed on the semiconductor substrate 101, for example.

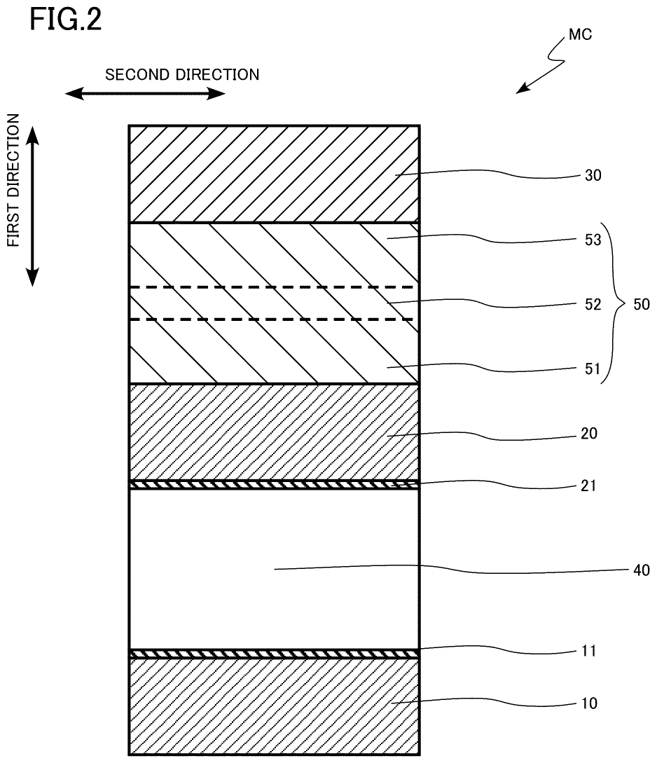

FIG. 2 is a schematic cross-sectional view of a memory cell in the memory device according to the first embodiment. FIG. 2 shows a cross section of one memory cell MC indicated by, for example, a dotted circle in the memory cell array 100 of FIG. 1. FIG. 2 shows a cross section parallel to a first direction connecting a first electrode 10 and a second electrode 20.

As shown in FIG. 2, the memory cell MC includes a first electrode 10, a second electrode 20, a third electrode 30, a switching layer 40, and a variable resistance layer 50. In addition, as shown in FIG. 2, the memory cell MC includes a first contact region 11 and a second contact region 21.

The first contact region 11 is an example of a region. The second contact region 21 is an example of a region.

The first electrode 10, the switching layer 40, the second electrode 20, the first contact region 11, and the second contact region 21 form a switching element of the memory cell MC. The second electrode 20, the variable resistance layer 50, and the third electrode 30 form a variable resistance element of the memory cell MC.

The first electrode 10 is connected to the word line 102. The first electrode 10 may be a part of the word line 102.

The first electrode 10 contains carbon (C). The first electrode 10 contains, for example, carbon (C) as a main component. The first electrode 10 includes, for example, a carbon layer. The first electrode 10 is, for example, a carbon layer. The carbon layer is, for example, amorphous.

The first electrode 10 contains carbon (C) at least on its face facing the switching layer 40. The first electrode 10 may have a portion that does not contain carbon (C), for example, on a side opposite to the face facing the switching layer 40. The first electrode 10 may include a metal layer or a metal compound layer that does not contain carbon (C), for example, on the side opposite to the face facing the switching layer 40.

The second electrode 20 is provided between the first electrode 10 and the third electrode 30.

The second electrode 20 contains carbon (C). The second electrode 20 contains, for example, carbon (C) as a main component. The second electrode 20 includes, for example, a carbon layer. The second electrode 20 is, for example, a carbon layer. The carbon layer is, for example, amorphous.

The second electrode 20 contains carbon (C) at least on its face facing the switching layer 40. The second electrode 20 may have a portion that does not contain carbon (C), for example, on a side opposite to the face facing the switching layer 40. The second electrode 20 may include a metal layer or a metal compound layer that does not contain carbon (C), for example, on the side opposite to the face facing the switching layer 40.

The third electrode 30 is connected to the bit line 103. The third electrode 30 is, for example, a metal or a metal compound. The third electrode 30 contains, for example, at least one material selected from a group consisting of carbon, carbon nitride, tungsten, tungsten carbide, tungsten nitride, titanium, titanium nitride, tantalum, tantalum carbide, and tantalum nitride. The third electrode 30 may be a part of the bit line 103.

The switching layer 40 is provided between the first electrode 10 and the second electrode 20. The thickness of the switching layer 40 in a first direction from the first electrode 10 to the second electrode 20 is, for example, equal to or more than 4 nm and equal to or less than 25 nm. The length of the switching layer 40 in a second direction perpendicular to the first direction is, for example, equal to or more than 10 nm and equal to or less than 50 nm.

The switching layer 40 has a function of suppressing an increase in half-select leakage current flowing through a half-selected cell. The switching layer 40 has a nonlinear current-voltage characteristic that a current increases abruptly at a specific threshold voltage.

The switching layer 40 contains a first oxide or an oxynitride of a first element. The switching layer 40 contains a second element and a third element. The switching layer 40 contains oxygen (O). The switching layer 40 contains or does not contain nitrogen (N).

The first element is at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg).

The oxide of the first element is, for example, an aluminum oxide, a silicon oxide, a germanium oxide, a zirconium oxide, a yttrium oxide, a tantalum oxide, a lanthanum oxide, a cerium oxide, a titanium oxide, a hafnium oxide, or a magnesium oxide. The oxynitride of the first element is, for example, an aluminum oxynitride, a silicon oxynitride, a germanium oxynitride, a zirconium oxynitride, a yttrium oxynitride, a tantalum oxynitride, a lanthanum oxynitride, a cerium oxynitride, a titanium oxynitride, a hafnium oxynitride, or a magnesium oxynitride.

The second element is an element different from the first element. The second element is at least one element selected from a group consisting of aluminum (Al), zinc (Zn), tin (Sn), gallium (Ga), bismuth (Bi), and indium (In). The third element is at least one element selected from a group consisting of tellurium (Te), sulfur (S), selenium (Se), and antimony (Sb).

The switching layer 40 contains, for example, a compound of the second element and the third element. Examples of the compound of the second element and the third element include aluminum telluride, zinc telluride, tin telluride, gallium telluride, bismuth telluride, indium telluride, aluminum sulfide, zinc sulfide, tin sulfide, gallium sulfide, bismuth sulfide, indium sulfide, aluminum selenide, zinc selenide, tin selenide, gallium selenide, bismuth selenide, indium selenide, aluminum antimonide, zinc antimonide, tin antimonide, gallium antimonide, bismuth antimonide, and indium antimonide.

The sum of the atomic concentration of the first element, the atomic concentration of the second element, the atomic concentration of the third element, the atomic concentration of oxygen (O), and the atomic concentration of nitrogen (N) in the switching layer 40 is, for example, equal to or more than 80 at % and equal to or less than 100 at %.

The variable resistance layer 50 is provided between the second electrode 20 and the third electrode 30. The variable resistance layer 50 includes a fixed layer 51, a tunnel layer 52, and a free layer 53. The variable resistance layer 50 includes a magnetic tunnel junction formed by the fixed layer 51, the tunnel layer 52, and the free layer 53.

The variable resistance layer 50 has a function of storing data by resistance change. The variable resistance layer 50 has, for example, a characteristic that the electrical resistance changes with the application of a predetermined voltage.

The fixed layer 51 is a ferromagnetic material. In the fixed layer 51, its magnetization direction does not change with respect to a predetermined write voltage, but is fixed to a specific direction.

The tunnel layer 52 is an insulator. Electrons pass through the tunnel layer 52 by the tunnel effect.

The free layer 53 is a ferromagnetic material. In the free layer 53, its magnetization direction changes with respect to a predetermined write voltage. The magnetization direction of the free layer 53 can be parallel to the magnetization direction of the fixed layer 51 or can be antiparallel to the magnetization direction of the fixed layer 51. For example, by applying a voltage between the second electrode 20 and the third electrode 30 so that a current flows between the third electrode 30 and the second electrode 20, the magnetization direction of the free layer 53 can be changed.

By changing the magnetization direction of the free layer 53, the electrical resistance of the variable resistance layer 50 changes. When the magnetization direction of the free layer 53 is antiparallel to the magnetization direction of the fixed layer 51, a high resistance state in which a current hardly flows is realized. On the other hand, when the magnetization direction of the free layer 53 is parallel to the magnetization direction of the fixed layer 51, a low resistance state in which a current flows easily is realized. In addition, the arrangement of the fixed layer 51 and the free layer 53 may be reversed. That is, the second electrode 20, the free layer 53, the tunnel layer 52, the fixed layer 51, and the third electrode 30 may be stacked in this order.

The first contact region 11 is provided between the first electrode 10 and the switching layer 40. The first contact region 11 is in contact with the first electrode 10. The first contact region 11 is in contact with the switching layer 40.

The first contact region 11 is in contact with a portion of the first electrode 10 containing carbon (C). The first electrode 10 includes, for example, a carbon layer, and the carbon layer is in contact with the first contact region 11.

The first contact region 11 has, for example, a layer shape. The thickness of the first contact region 11 in a first direction from the first electrode 10 to the second electrode 20 is, for example, equal to or more than 0.1 nm and equal to or less than 5 nm. The thickness of the first contact region 11 in the first direction from the first electrode 10 to the second electrode 20 is, for example, smaller than the thickness of the first electrode 10 in the first direction, the thickness of the second electrode 20 in the first direction, and the thickness of the switching layer 40 in the first direction.

The first contact region 11 contains at least one fourth element selected from a group consisting of titanium (Ti), tungsten (W), molybdenum (Mo), tantalum (Ta), aluminum (Al), boron (B), chromium (Cr), hafnium (Hf), niobium (Nb), vanadium (V), silicon (Si), and zirconium (Zr). The fourth element is different from the first element, the second element, and the third element contained in the switching layer 40.

The switching layer 40 contains or does not contain the fourth element. For example, when the switching layer 40 contains the fourth element, the atomic concentration of the fourth element in the first contact region 11 is higher than the atomic concentration of the fourth element in the switching layer 40.

The first electrode 10 contains or does not contain the fourth element. For example, when the first electrode 10 contains the fourth element, the atomic concentration of the fourth element in the first contact region 11 is higher than the atomic concentration of the fourth element in the first electrode 10.

The first contact region 11 contains, for example, a fifth element, which is at least one element of nitrogen (N) and carbon (C).

The first contact region 11 contains, for example, a sixth element, which is at least one element selected from a group consisting of zinc (Zn), gallium (Ga), germanium (Ge), tellurium (Te), lanthanum (La), and cerium (Ce).

The first contact region 11 contains, for example, titanium (Ti) and nitrogen (N). The first contact region 11 contains, for example, titanium nitride.

The first contact region 11 contains, for example, tungsten (W) and nitrogen (N). The first contact region 11 contains, for example, tungsten nitride.

The first contact region 11 contains, for example, at least one element selected from a group consisting of the first element, the second element, and the third element. When the first contact region 11 contains at least one element selected from a group consisting of the first element, the second element, and the third element, the atomic concentration of the at least one element in the first contact region 11 is lower than the atomic concentration of the at least one element in the switching layer 40.

The second contact region 21 is provided between the second electrode 20 and the switching layer 40. The second contact region 21 is in contact with the second electrode 20. The second contact region 21 is in contact with the switching layer 40.

The second contact region 21 is in contact with a portion of the second electrode 20 containing carbon (C). The second electrode 20 contains, for example, a carbon layer, and the carbon layer is in contact with the second contact region 21.

The second contact region 21 has, for example, a layer shape. The thickness of the second contact region 21 in the first direction from the first electrode 10 to the second electrode 20 is, for example, equal to or more than 0.1 nm and equal to or less than 5 nm. The thickness of the second contact region 21 in the first direction is, for example, smaller than the thickness of the first electrode 10 in the first direction, the thickness of the second electrode 20 in the first direction, and the thickness of the switching layer 40 in the first direction.

The second contact region 21 contains at least one fourth element selected from a group consisting of titanium (Ti), tungsten (W), molybdenum (Mo), tantalum (Ta), aluminum (Al), boron (B), chromium (Cr), hafnium (Hf), niobium (Nb), vanadium (V), silicon (Si), and zirconium (Zr). The fourth element is different from the first element, the second element, and the third element contained in the switching layer 40.

The switching layer 40 contains or does not contain the fourth element. For example, when the switching layer 40 contains the fourth element, the atomic concentration of the fourth element in the second contact region 21 is higher than the atomic concentration of the fourth element in the switching layer 40.

The second electrode 20 contains or does not contain the fourth element. For example, when the second electrode 20 contains the fourth element, the atomic concentration of the fourth element in the second contact region 21 is higher than the atomic concentration of the fourth element in the second electrode 20.

The second contact region 21 contains, for example, a fifth element, which is at least one element of nitrogen (N) and carbon (C).

The second contact region 21 contains, for example, a sixth element, which is at least one element selected from a group consisting of zinc (Zn), gallium (Ga), germanium (Ge), tellurium (Te), lanthanum (La), and cerium (Ce).

The second contact region 21 contains, for example, titanium (Ti) and nitrogen (N). The second contact region 21 contains, for example, titanium nitride.

The second contact region 21 contains, for example, tungsten (W) and nitrogen (N). The second contact region 21 contains, for example, tungsten nitride.

The second contact region 21 contains, for example, at least one element selected from a group consisting of the first element, the second element, and the third element. When the second contact region 21 contains at least one element selected from a group consisting of the first element, the second element, and the third element, the atomic concentration of the at least one element in the second contact region 21 is lower than the atomic concentration of the at least one element in the switching layer 40.

In addition, the fourth element contained in the first contact region 11 and the fourth element contained in the second contact region 21 may be different types of elements. In addition, the fifth element contained in the first contact region 11 and the fifth element contained in the second contact region 21 may be different types of elements. In addition, the sixth element contained in the first contact region 11 and the sixth element contained in the second contact region 21 may be different types of elements.

Next, the function and effect of the memory device according to the first embodiment will be described.

In the memory device according to the first embodiment, the resistance of the variable resistance layer 50 is changed by changing the magnetization direction of the free layer 53 as described above. When the magnetization direction of the free layer 53 is antiparallel to the magnetization direction of the fixed layer 51, a high resistance state in which a current hardly flows is realized. On the other hand, when the magnetization direction of the free layer 53 is parallel to the magnetization direction of the fixed layer 51, a low resistance state in which a current flows easily is realized.

For example, the high resistance state of the variable resistance layer 50 is defined as data “1”, and the low resistance state of the variable resistance layer 50 is defined as data “0”. Since the memory cell MC can maintain different resistance states, it is possible to store 1-bit data of “0” and “1”. Writing to one memory cell MC is performed by applying a voltage between the bit line 103 and the word line 102 connected to the memory cell MC so that a current flows between the bit line 103 and the word line 102 connected to the memory cell MC.

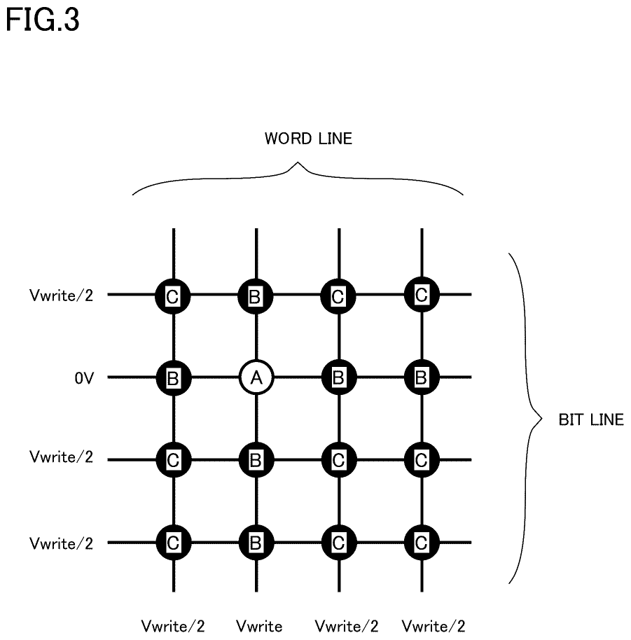

FIG. 3 is an explanatory diagram of the function of the memory device according to the first embodiment. FIG. 3 shows a voltage applied to the memory cell MC when one memory cell MC in the memory cell array is selected for a write operation. The intersection of word lines and bit lines represents each memory cell MC.

The selected memory cell MC is a memory cell A (selected cell). A write voltage Vwrite is applied to the word line connected to the memory cell A. In addition, 0 V is applied to the bit line connected to the memory cell A.

Hereinafter, a case in which half (Vwrite/2) the write voltage is applied to the word lines and bit lines that are not connected to the memory cell A will be described as an example.

A voltage applied to memory cells C (non-selected cells) connected to the word lines and bit lines that are not connected to the memory cell A is 0 V. That is, no voltage is applied.

On the other hand, half (Vwrite/2) the write voltage Vwrite is applied to memory cells B (half-selected cells) connected to the word lines or bit lines connected to the memory cell A. Therefore, a half-select leakage current flows through the memory cell B (half-selected cell).

In addition, as an application method other than those described above, a method may be used in which half the write voltage (Vwrite/2) is applied to the word line connected to the memory cell A, a negative voltage (−Vwrite/2) of half the write voltage is applied to the bit line, and 0 V is applied to the word line and the bit line that are not connected to the memory cell A.

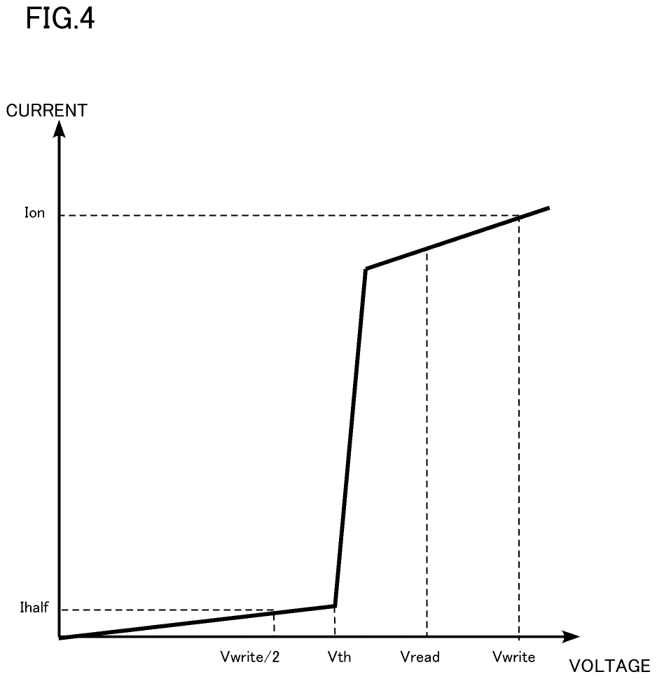

FIG. 4 is an explanatory diagram of the current-voltage characteristics of a switching element in the first embodiment. The horizontal axis indicates a voltage applied to the switching element, and the vertical axis indicates a current flowing through the switching element.

The switching element has a nonlinear current-voltage characteristic that a current increases abruptly at a threshold voltage Vth. The threshold voltage Vth is, for example, equal to or more than 0.5 V and equal to or less than 3 V.

The write voltage Vwrite is set such that the write voltage Vwrite is higher than the threshold voltage Vth and half (Vwrite/2) the write voltage Vwrite is lower than the threshold voltage Vth. The current flowing through the switching element when the write voltage Vwrite is applied is an on-current (Ion in FIG. 4). The current flowing through the switching element when half (Vwrite/2) the write voltage Vwrite is applied is a half-select leakage current (Ihalf in FIG. 4).

In addition, a read voltage Vread of the memory cell MC is set to a voltage higher than the threshold voltage Vth and lower than the write voltage Vwrite, as shown in FIG. 4, for example. Therefore, the half-select leakage current flowing through the half-selected cell can also be suppressed when reading the memory cell MC.

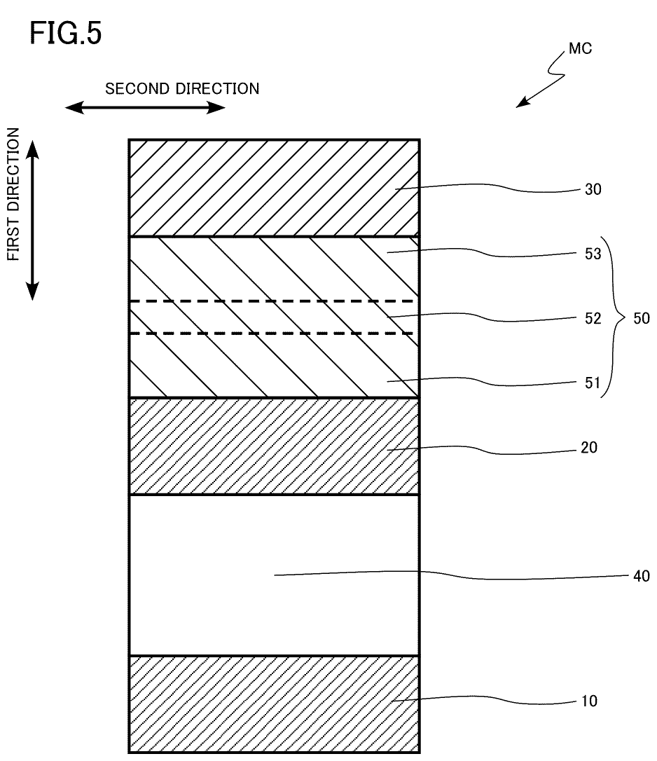

FIG. 5 is a schematic cross-sectional view of a memory cell of a memory device according to a comparative example. FIG. 5 is a diagram corresponding to FIG. 2 in the first embodiment.

A memory cell MC of the memory device according to the comparative example is different from the memory cell MC in the first embodiment in that the memory cell MC of the memory device according to the comparative example does not include the first contact region 11 and the second contact region 21.

The memory cell MC of the memory device according to the comparative example has low adhesion between the first electrode 10 and the switching layer 40 or low adhesion between the second electrode 20 and the switching layer 40. Therefore, film peeling may occur. If film peeling occurs between the electrode and the switching layer 40, for example, the electrical resistance between the electrode and the switching layer 40 increases. As a result, the memory cell MC may not operate.

The film peeling in the memory cell MC of the memory device according to the comparative example is thought to be caused by the weak bonding force of the chemical bond between the atoms that make up the electrode and the atoms that make up the switching layer 40. It is thought that the adhesion between the electrode and the switching layer 40 is low due to the weak bonding force of the chemical bond between the atoms that make up the electrode and the atoms that make up the switching layer 40.

The memory cell MC in the first embodiment includes the first contact region 11 containing the fourth element between the first electrode 10 and the switching layer 40. Since the memory cell MC in the first embodiment includes the first contact region 11, film peeling between the first electrode 10 and the switching layer 40 is suppressed.

The fourth element is an element that easily chemically bonds with carbon (C) contained in the first electrode 10 and the second element or the third element contained in the switching layer 40. For this reason, the bonding force of the chemical bond between the atoms that make up the first contact region 11 and the atoms that make up the first electrode 10 increases. In addition, the bonding force between the atoms that make up the first contact region 11 and the atoms that make up the switching layer 40 increases. Therefore, the adhesion between the first electrode 10 and the switching layer 40 is improved, and film peeling between the first electrode 10 and the switching layer 40 is suppressed.

For example, the first element is zirconium (Zr), the second element is zinc (Zn), the third element is tellurium (Te), and the fourth element is titanium (Ti).

In this case, the switching layer 40 contains, for example, zirconium oxide, which is an oxide of zirconium (Zr), and zinc telluride, which is a compound of zinc (Zn) and tellurium (Te). In addition, the first contact region 11 contains titanium (Ti).

Titanium (Ti) bonds with carbon (C) contained in the first electrode 10 to form, for example, titanium carbide. In addition, titanium (Ti) bonds with tellurium (Te) to form, for example, titanium telluride.

It is preferable that the fourth element is at least one element selected from a group consisting of aluminum (Al), silicon (Si), boron (B), vanadium (V), and molybdenum (Mo). Since the above element forms a solid solution with the oxide of the first element, the adhesion between the first electrode 10 and the switching layer 40 is further improved.

From the viewpoint of suppressing the occurrence of a situation in which the fourth element diffuses into the switching layer 40 to cause fluctuations in the characteristics of the switching layer 40, it is preferable that the first contact region 11 contains a fifth element, which is at least one element of nitrogen (N) and carbon (C).

For example, it is assumed that the first element is zirconium (Zr), the second element is zinc (Zn), the third element is tellurium (Te), the fourth element is titanium (Ti), and the fifth element is nitrogen (N).

In this case, the switching layer 40 contains, for example, zirconium oxide, which is an oxide of zirconium (Zr), and zinc telluride, which is a compound of zinc (Zn) and tellurium (Te). In addition, the first contact region 11 contains, for example, titanium nitride.

It is preferable that the first contact region 11 contains a sixth element, which is at least one element selected from a group consisting of zinc (Zn), gallium (Ga), germanium (Ge), tellurium (Te), lanthanum (La), and cerium (Ce). The sixth element forms a compound with the oxide of the first element. Therefore, the adhesion between the first electrode 10 and the switching layer 40 is further improved.

It is preferable that the first contact region 11 contains at least one element selected from a group consisting of the first element, the second element, and the third element. Since the first contact region 11 contains at least one of the above elements, the adhesion between the first electrode 10 and the switching layer 40 is further improved.

The memory cell MC in the first embodiment includes the second contact region 21 containing the fourth element between the second electrode 20 and the switching layer 40. Therefore, film peeling between the second electrode 20 and the switching layer 40 is suppressed, as in the case between the first electrode 10 and the switching layer 40.

From the viewpoint of facilitating processing on the memory cell MC and suppressing excessive diffusion of the fourth element into the switching layer 40, it is preferable that the thicknesses of the first contact region 11 and the second contact region 21 in the first direction from the first electrode 10 to the second electrode 20 are smaller than the thickness of the first electrode 10 in the first direction, the thickness of the second electrode 20 in the first direction, and the thickness of the switching layer 40 in the first direction. In addition, from a similar viewpoint, the thicknesses of the first contact region 11 and the second contact region 21 in the first direction from the first electrode 10 to the second electrode 20 are preferably equal to or less than 5 nm, more preferably equal to or less than 3 nm, and even more preferably equal to or less than 1 nm.

The first contact region 11 and the second contact region 21 are formed by using, for example, an atomic layer deposition method (ALD method) or a sputtering method.

According to the first embodiment, it is possible to realize a switching element in which film peeling between the first electrode 10 and the switching layer 40 and film peeling between the second electrode 20 and the switching layer 40 are suppressed. Therefore, it is possible to realize a memory device with excellent characteristics.

### First Modification Example

A memory device according to a first modification example of the first embodiment is different from the memory device according to the first embodiment in that the memory device according to the first modification example of the first embodiment does not include a region between the second electrode and the switching layer.

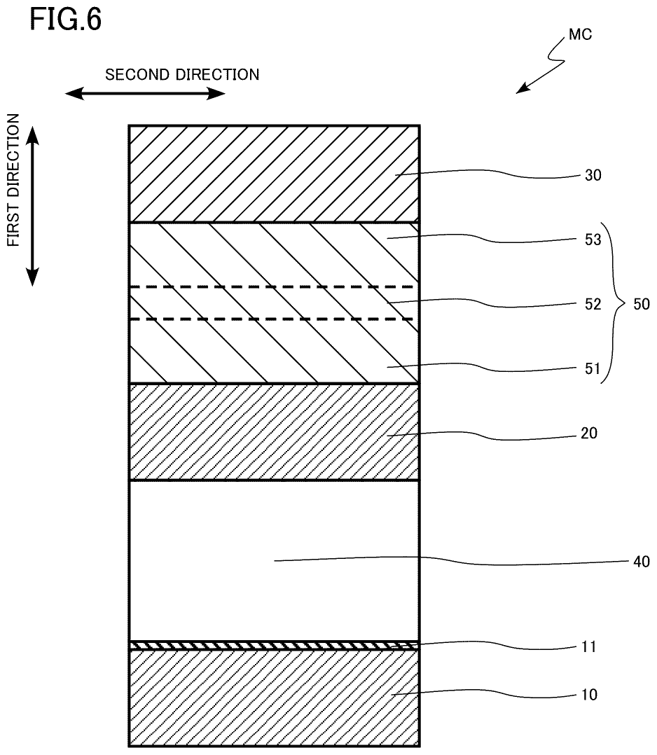

FIG. 6 is a schematic cross-sectional view of a memory cell in the memory device according to the first modification example of the first embodiment. FIG. 6 is a diagram corresponding to FIG. 2 in the first embodiment.

In a memory cell MC of the memory device according to the first modification example of the first embodiment, the second contact region 21 is not provided between the second electrode 20 and the switching layer 40.

The second electrode 20 contains or does not contain carbon (C).

The second electrode 20 is, for example, a metal or a metal compound. The second electrode 20 contains, for example, at least one material selected from a group consisting of tungsten, tungsten nitride, titanium, titanium nitride, tantalum, and tantalum nitride.

According to the first modification example of the first embodiment, as in the first embodiment, it is possible to realize a switching element in which film peeling between the first electrode 10 and the switching layer 40 is suppressed. Therefore, it is possible to realize a memory device with excellent characteristics.

### Second Modification Example

A memory device according to a second modification example of the first embodiment is different from the memory device according to the first embodiment in that the memory device according to the second modification example of the first embodiment does not include a region between the first electrode and the switching layer.

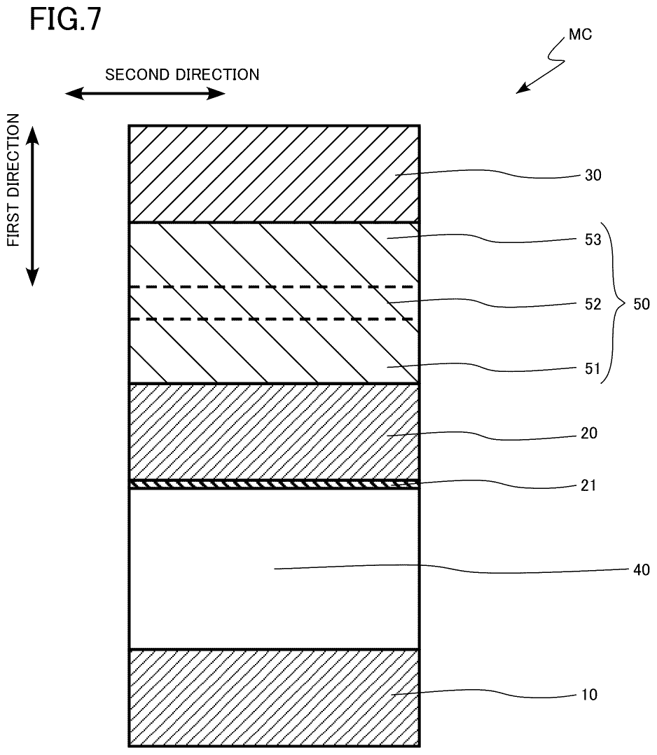

FIG. 7 is a schematic cross-sectional view of a memory cell in the memory device according to the second modification example of the first embodiment. FIG. 7 is a diagram corresponding to FIG. 2 in the first embodiment.

In a memory cell MC of the memory device according to the second modification example of the first embodiment, the first contact region 11 is not provided between the first electrode 10 and the switching layer 40.

The first electrode 10 contains or does not contain carbon (C).

The first electrode 10 is, for example, a metal or a metal compound. The first electrode 10 contains, for example, at least one material selected from a group consisting of tungsten, tungsten nitride, titanium, titanium nitride, tantalum, and tantalum nitride. According to the second modification example of the first embodiment, as in the first embodiment, it is possible to realize a switching element in which film peeling between the second electrode 20 and the switching layer 40 is suppressed. Therefore, it is possible to realize a memory device with excellent characteristics.

### Third Modification Example

A memory device according to a third modification example of the first embodiment is different from the memory device according to the first embodiment in that a region has a plurality of portions spaced from each other along a face where a switching layer faces a first electrode and a face where the switching layer faces a second electrode.

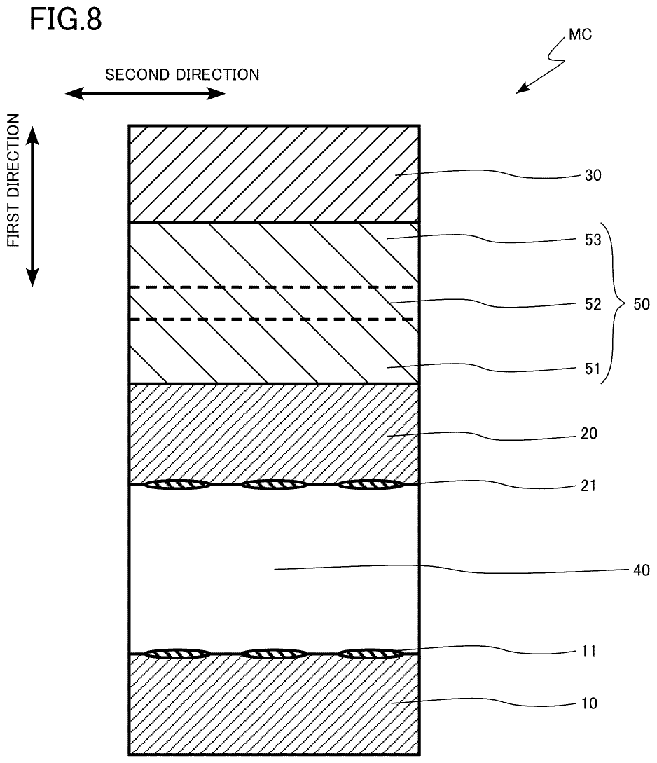

FIG. 8 is a schematic cross-sectional view of a memory cell in the memory device according to the third modification example of the first embodiment. FIG. 8 is a diagram corresponding to FIG. 2 in the first embodiment.

In a memory cell MC of the memory device according to the third modification example of the first embodiment, the first contact region 11 between the first electrode 10 and the switching layer 40 has a plurality of portions spaced from each other along a face where the switching layer 40 faces the first electrode 10. In other words, the first contact region 11 has a plurality of portions spaced from each other in the second direction.

In addition, in the memory cell MC of the memory device according to the third modification example of the first embodiment, the second contact region 21 between the second electrode 20 and the switching layer 40 has a plurality of portions spaced from each other along a face where the switching layer 40 faces the second electrode 20. In other words, the second contact region 21 has a plurality of portions spaced from each other in the second direction.

According to the third modification example of the first embodiment, as in the first embodiment, it is possible to realize a switching element in which film peeling between the first electrode 10 and the switching layer 40 and film peeling between the second electrode 20 and the switching layer 40 are suppressed. Therefore, it is possible to realize a memory device with excellent characteristics.

### Fourth Modification Example

A memory device according to a fourth modification example of the first embodiment is different from the memory device according to the first embodiment in that the first electrode and the second electrode do not contain carbon (C).

A memory cell MC of the memory device according to the fourth modification example of the first embodiment includes a first electrode 10, a second electrode 20, a third electrode 30, a switching layer 40, and a variable resistance layer 50, as in the memory cell MC of the memory device according to the first embodiment. In addition, the memory cell MC includes a first contact region 11 and a second contact region 21.

In the memory cell MC of the memory device according to the fourth modification example of the first embodiment, the first electrode 10 and the second electrode 20 do not contain carbon (C).

Each of the first electrode 10 and the second electrode 20 is, for example, a metal or a metal compound. The first electrode 10 contains, for example, at least one material selected from a group consisting of tungsten, tungsten nitride, titanium, titanium nitride, tantalum, and tantalum nitride.

According to the fourth modification example of the first embodiment, it is possible to realize a switching element in which film peeling between the first electrode 10 and the switching layer 40 and film peeling between the second electrode 20 and the switching layer 40 are suppressed. Therefore, it is possible to realize a memory device with excellent characteristics.

### Second Embodiment

A memory device according to a second embodiment is different from the memory device according to the first embodiment in that the memory device according to the second embodiment is a resistive random access memory (ReRAM). Hereinafter, the description of a part of the content overlapping the first embodiment will be omitted.

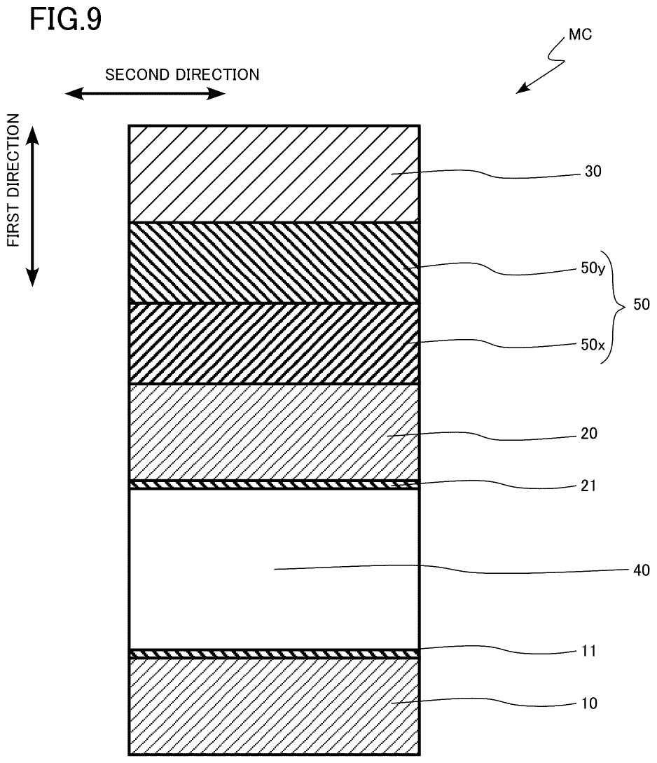

FIG. 9 is a schematic cross-sectional view of a memory cell in the memory device according to the second embodiment. FIG. 9 shows a cross section of one memory cell MC indicated by, for example, a dotted circle in the memory cell array 100 of FIG. 1.

As shown in FIG. 9, the memory cell MC includes a first electrode 10, a second electrode 20, a third electrode 30, a switching layer 40, and a variable resistance layer 50. In addition, as shown in FIG. 9, the memory cell MC includes a first contact region 11 and a second contact region 21.

The first contact region 11 is an example of a region. The second contact region 21 is an example of a region.

The configurations of the first electrode 10, the second electrode 20, the switching layer 40, the first contact region 11, and the second contact region 21 are the same as those in the memory device according to the first embodiment.

The variable resistance layer 50 includes the high resistance layer 50x and the low resistance layer 50y.

The high resistance layer 50x is, for example, a metal oxide. The high resistance layer 50x is, for example, an aluminum oxide, a hafnium oxide, a zirconium oxide, a tantalum oxide, or a niobium oxide.

The low resistance layer 50y is, for example, a metal oxide. The low resistance layer 50y is, for example, a titanium oxide, a niobium oxide, a tantalum oxide, or a tungsten oxide.

The variable resistance layer 50 has a function of storing data by resistance change. The variable resistance layer 50 has, for example, a characteristic that the electrical resistance changes with the application of a predetermined voltage.

By applying a voltage to the variable resistance layer 50, the variable resistance layer 50 changes from a high resistance state to a low resistance state or from a low resistance state to a high resistance state. By applying a voltage to the variable resistance layer 50, oxygen ions move between the high resistance layer 50x and the low resistance layer 50y, so that the amount of oxygen deficiency (the amount of oxygen vacancies) in the low resistance layer 50y changes. The electrical conductivity of the variable resistance layer 50 changes according to the amount of oxygen deficiency in the low resistance layer 50y. The low resistance layer 50y is a so-called vacancy modulated conductive oxide.

For example, the high resistance state is defined as data “1”, and the low resistance state is defined as data “0”. The memory cell MC can store 1-bit data of “0” and “1”.

As described above, according to the memory device according to the second embodiment, as in the first embodiment, it is possible to realize a switching element in which film peeling between the first electrode 10 and the switching layer 40 and film peeling between the second electrode 20 and the switching layer 40 are suppressed. Therefore, it is possible to realize a memory device with excellent characteristics.

### Third Embodiment

A memory device according to a third embodiment includes a first electrode, a second electrode, a memory layer provided between the first electrode and the second electrode, and a memory cell including a region. The memory layer contains an oxide or oxynitride of a first element being at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg); a second element being different from the first element, and being at least one element selected from a group consisting of aluminum (Al), zinc (Zn), tin (Sn), gallium (Ga), bismuth (Bi), and indium (In); and a third element being at least one element selected from a group consisting of tellurium (Te), sulfur (S), selenium (Se), and antimony (Sb). At least one electrode of the first electrode and the second electrode contains carbon (C). The region is provided between at least one of the at least one electrode and the memory layer, and contains a fourth element, the fourth element being different from the first element, the second element, and the third element, and the fourth element being at least one element selected from a group consisting of titanium (Ti), tungsten (W), molybdenum (Mo), tantalum (Ta), aluminum (Al), boron (B), chromium (Cr), hafnium (Hf), niobium (Nb), vanadium (V), silicon (Si), and zirconium (Zr).

In addition, the memory device according to the third embodiment further includes a plurality of first wirings and a plurality of second wirings crossing the plurality of first wirings. In addition, the memory cell is provided in a portion where one of the plurality of first wirings and one of the plurality of second wirings cross each other.

The memory device according to the third embodiment is different from the memory device according to the first embodiment in that the memory cell does not include a third electrode and a variable resistance layer and includes a structure similar to the switching layer in the first embodiment as a memory layer. Hereinafter, the description of a part of the content overlapping the first embodiment will be omitted.

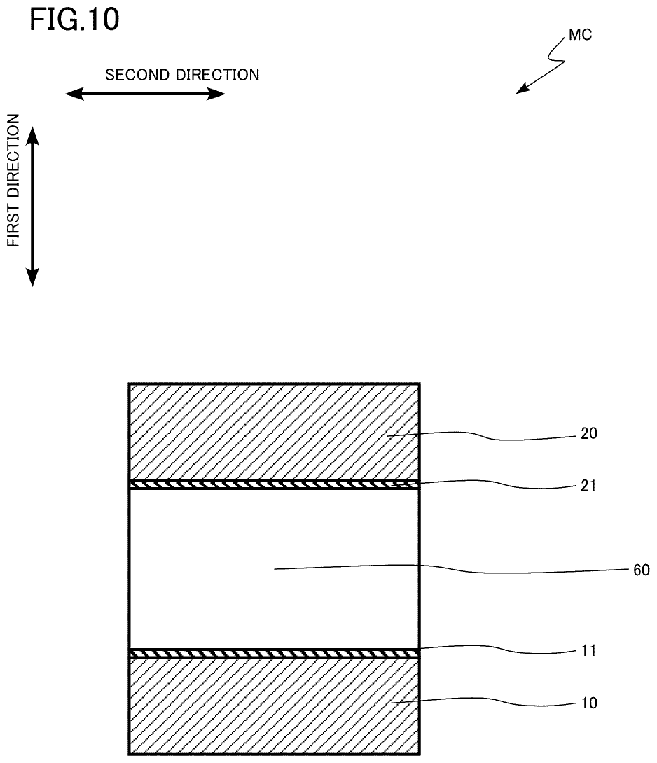

FIG. 10 is a schematic cross-sectional view of a memory cell in the memory device according to the third embodiment. FIG. 10 shows a cross section of one memory cell MC indicated by, for example, a dotted circle in the memory cell array 100 of FIG. 1.

As shown in FIG. 10, the memory cell MC includes a first electrode 10, a second electrode 20, and a memory layer 60. In addition, as shown in FIG. 10, the memory cell MC includes a first contact region 11 and a second contact region 21.

The first contact region 11 is an example of a region. The second contact region 21 is an example of a region.

The first electrode 10, the memory layer 60, the second electrode 20, the first contact region 11, and the second contact region 21 form a memory element of the memory cell MC. The memory element of the memory cell MC has a switching function and an information storage function.

The memory layer 60 has a configuration similar to that of the switching layer 40 in the first embodiment.

The memory layer 60 is provided between the first electrode 10 and the second electrode 20.

The memory layer 60 has a nonlinear current-voltage characteristic that a current increases abruptly at a specific threshold voltage. In addition, the memory layer 60 has a characteristic that the threshold voltage changes with the application of a predetermined voltage. The memory layer 60 has a characteristic that the electrical resistance changes with the application of a predetermined voltage. In the third embodiment, the high resistance state is a state in which the resistance of the memory layer 60 is relatively high at the read voltage. In addition, in the third embodiment, the low resistance state is a state in which the resistance of the memory layer 60 is relatively low at the read voltage.

The memory layer 60 has a function of suppressing an increase in half-select leakage current flowing through the half-selected cell. In addition, the memory layer 60 has a function of storing data by resistance change. The memory layer 60 is a single layer, and realizes the function of the switching layer 40 and the function of the variable resistance layer 50 in the first embodiment.

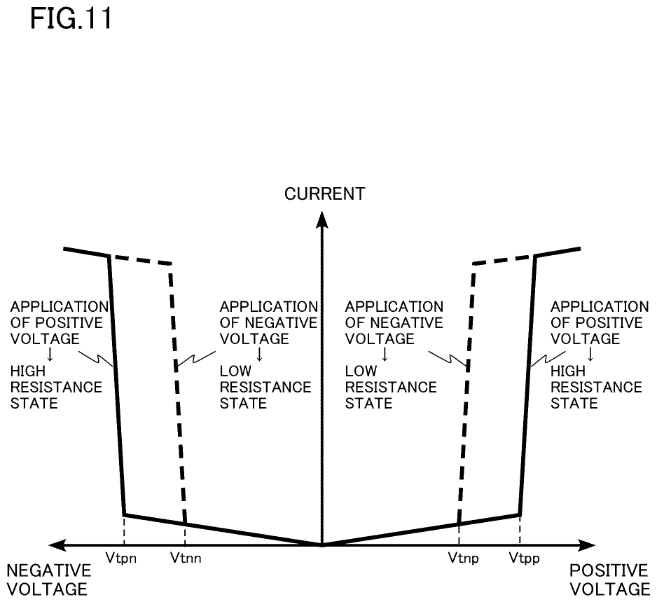

FIG. 11 is an explanatory diagram of the current-voltage characteristics of the memory element in the third embodiment. The horizontal axis indicates a voltage applied to the memory element, and the vertical axis indicates a current flowing through the memory element. In FIG. 11, the horizontal axis indicates a voltage applied to the second electrode 20 with the electric potential of the first electrode 10 as a reference. FIG. 11 shows the current-voltage characteristics of the memory layer 60 in the third embodiment. FIG. 11 shows the current-voltage characteristics of the memory cell MC in the third embodiment.

The memory element in the third embodiment shows different current-voltage characteristics when a predetermined positive voltage is applied to the second electrode 20 and when a predetermined negative voltage is applied to the second electrode 20. In FIG. 11, the solid line indicates the current-voltage characteristics when a predetermined positive voltage is applied to the second electrode 20, and the dotted line indicates the current-voltage characteristics when a predetermined negative voltage is applied to the second electrode 20.

When a predetermined positive voltage is applied to the second electrode 20, the current increases abruptly at a first positive voltage side threshold voltage Vtpp on the positive voltage side. In addition, when a predetermined positive voltage is applied to the second electrode 20, the current increases abruptly at a first negative voltage side threshold voltage Vtpn on the negative voltage side.

On the other hand, when a predetermined negative voltage is applied to the second electrode 20, the current increases abruptly at a second positive voltage side threshold voltage Vtnp on the positive voltage side. In addition, when a predetermined negative voltage is applied to the second electrode 20, the current increases abruptly at a second negative voltage side threshold voltage Vtnn on the negative voltage side.

The first positive voltage side threshold voltage Vtpp is higher than the second positive voltage side threshold voltage Vtnp. In addition, the first negative voltage side threshold voltage Vtpn is lower than the second negative voltage side threshold voltage Vtnn.

The memory element in the third embodiment can have a high resistance state and a low resistance state on both the positive voltage side and the negative voltage side. When a predetermined positive voltage is applied to the second electrode 20, a high resistance state is realized on both the positive voltage side and the negative voltage side. On the other hand, when a predetermined negative voltage is applied to the second electrode 20, a low resistance state is realized on both the positive voltage side and the negative voltage side. Hereinafter, the high resistance state will be defined as data “1”, and the low resistance state will be defined as data “0”. The memory cell MC can store 1-bit data of “0” and “1”.

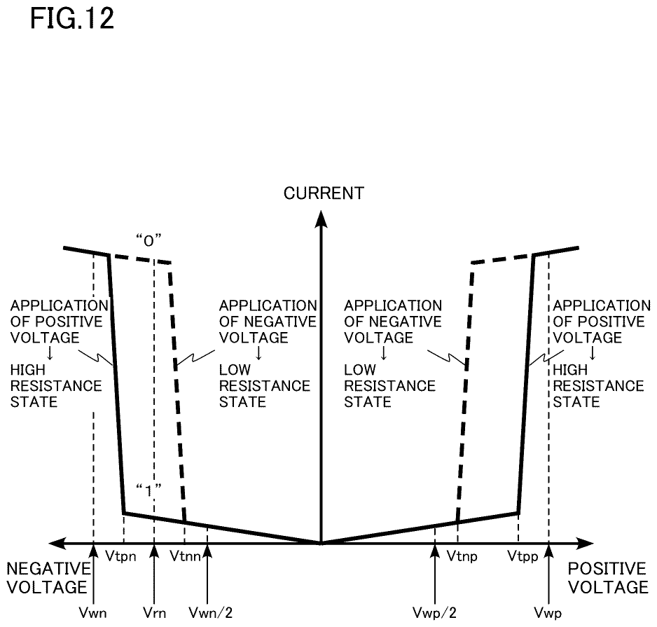

FIG. 12 is an explanatory diagram of a first operation example of the memory operation of the memory device according to the third embodiment. FIG. 12 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the first operation example, the high resistance state and the low resistance state on the negative voltage side are used for the memory operation. In the first operation example, the negative side read voltage Vrn is used as a read voltage.

When writing data “1” to the selected cell, the positive side write voltage Vwp is applied to the second electrode 20. The positive side write voltage Vwp is a voltage higher than the first positive voltage side threshold voltage Vtpp. By applying the positive side write voltage Vwp to the second electrode 20, a high resistance state is realized on the negative voltage side, and data “1” is written to the selected cell.

When writing data “O” to the selected cell, the negative side write voltage Vwn is applied to the second electrode 20. The negative side write voltage Vwn is a voltage lower than the first negative voltage side threshold voltage Vtpn. By applying the negative side write voltage Vwn to the second electrode 20, a low resistance state is realized on the negative voltage side, and data “0” is written to the selected cell.

In the first operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the first operation example, regardless of whether the data of the selected cell is data “1” or data “0”, the application of the negative side read voltage Vrn does not destroy the data. In other words, in the case of the first operation example, non-destructive reading is possible regardless of whether the data of the selected cell is data “1” or data “0”.

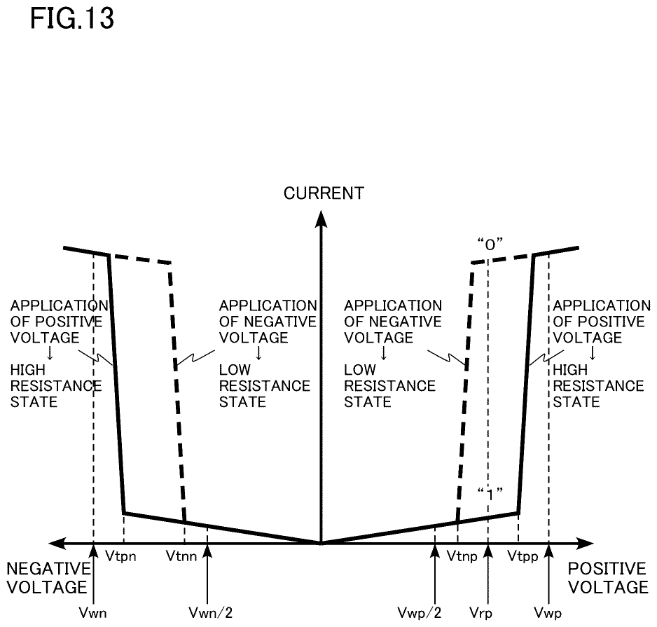

FIG. 13 is an explanatory diagram of a second operation example of the memory operation of the memory device according to the third embodiment. FIG. 13 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the second operation example, the high resistance state and the low resistance state on the positive voltage side are used for the memory operation. In the second operation example, the positive side read voltage Vrp is used as a read voltage.

When writing data “1” to the selected cell, the positive side write voltage Vwp is applied to the second electrode 20. The positive side write voltage Vwp is a voltage higher than the first positive voltage side threshold voltage Vtpp. By applying the positive side write voltage Vwp to the second electrode 20, a high resistance state is realized on the positive voltage side, and data “1” is written to the selected cell.

When writing data “0” to the selected cell, the negative side write voltage Vwn is applied to the second electrode 20. The negative side write voltage Vwn is a voltage lower than the first negative voltage side threshold voltage Vtpn. By applying the negative side write voltage Vwn to the second electrode 20, a low resistance state is realized on the positive voltage side, and data “0” is written to the selected cell.

In the second operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the second operation example, when the data of the selected cell is data “1”, the application of the positive side read voltage Vrp does not destroy the data. In other words, in the case of the second operation example, non-destructive reading is possible if the data of the selected cell is data “1”.

On the other hand, when the data of the selected cell is data “0”, the application of the positive side read voltage Vrp higher than the second positive voltage side threshold voltage Vtnp may cause a current to flow. As a result, the data of the selected cell may change to data “1”. In other words, in the case of the second operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

### First Modification Example

A memory device according to a first modification example of the third embodiment is different from the memory device according to the third embodiment in that the current-voltage characteristics of the memory elements are different.

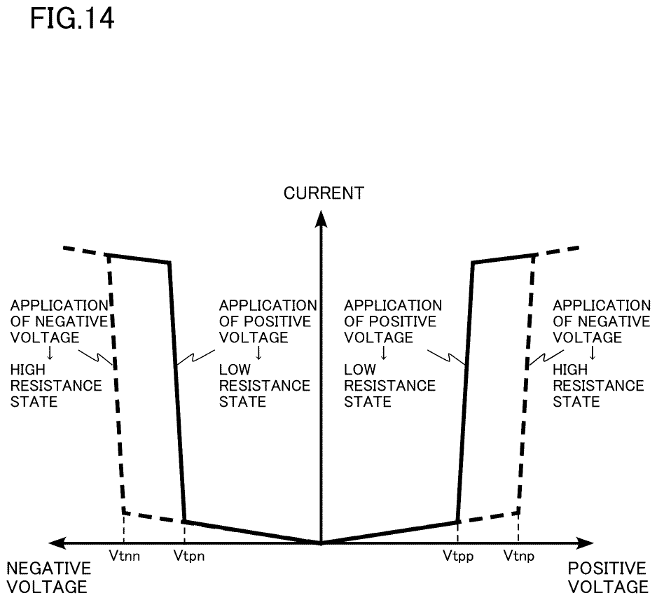

FIG. 14 is an explanatory diagram of the current-voltage characteristics of a memory element in the first modification example of the third embodiment. The horizontal axis indicates a voltage applied to the memory element, and the vertical axis indicates a current flowing through the memory element. In FIG. 14, the horizontal axis indicates a voltage applied to the second electrode 20 with the electric potential of the first electrode 10 as a reference. FIG. 14 shows the current-voltage characteristics of the memory layer 60 in the first modification example of the third embodiment. FIG. 14 shows the current-voltage characteristics of the memory cell MC in the first modification example of the third embodiment.

The memory element in the first modification example of the third embodiment shows different current-voltage characteristics when a predetermined positive voltage is applied to the second electrode 20 and when a predetermined negative voltage is applied to the second electrode 20. In FIG. 14, the solid line indicates the current-voltage characteristics when a predetermined positive voltage is applied to the second electrode 20, and the dotted line indicates the current-voltage characteristics when a predetermined negative voltage is applied to the second electrode 20.

When a predetermined positive voltage is applied to the second electrode 20, the current increases abruptly at a first positive voltage side threshold voltage Vtpp on the positive voltage side. In addition, when a predetermined positive voltage is applied to the second electrode 20, the current increases abruptly at a first negative voltage side threshold voltage Vtpn on the negative voltage side.

On the other hand, when a predetermined negative voltage is applied to the second electrode 20, the current increases abruptly at a second positive voltage side threshold voltage Vtnp on the positive voltage side. In addition, when a predetermined negative voltage is applied to the second electrode 20, the current increases abruptly at a second negative voltage side threshold voltage Vtnn on the negative voltage side.

The first positive voltage side threshold voltage Vtpp is lower than the second positive voltage side threshold voltage Vtnp. In addition, the first negative voltage side threshold voltage Vtpn is higher than the second negative voltage side threshold voltage Vtnn.

The memory element in the first modification example of the third embodiment can have a high resistance state and a low resistance state on both the positive voltage side and the negative voltage side. When a predetermined positive voltage is applied to the second electrode 20, a low resistance state is realized on both the positive voltage side and the negative voltage side. On the other hand, when a predetermined negative voltage is applied to the second electrode 20, a high resistance state is realized on both the positive voltage side and the negative voltage side. Hereinafter, the high resistance state will be defined as data “1”, and the low resistance state will be defined as data “0”. The memory cell MC can store 1-bit data of “0” and “1”.

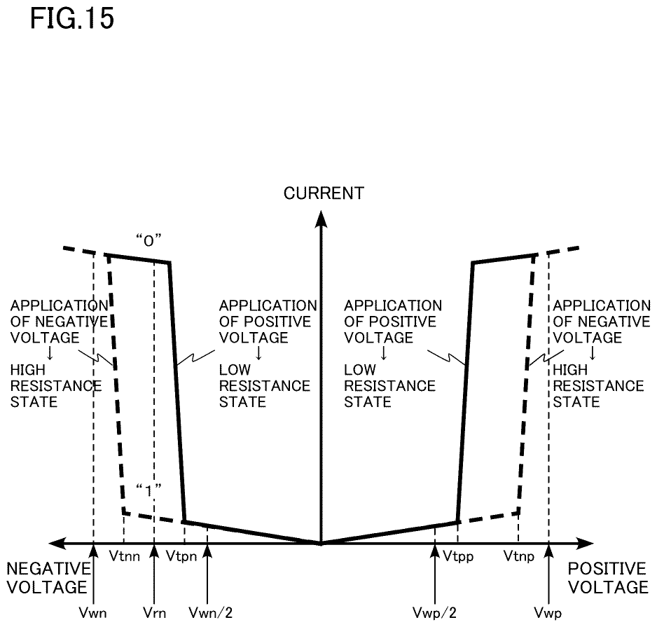

FIG. 15 is an explanatory diagram of a third operation example of the memory operation of the memory device according to the first modification example of the third embodiment. FIG. 15 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the third operation example, the high resistance state and the low resistance state on the negative voltage side are used for the memory operation. In the third operation example, the negative side read voltage Vrn is used as a read voltage.

When writing data “1” to the selected cell, the negative side write voltage Vwn is applied to the second electrode 20. The negative side write voltage Vwn is a voltage lower than the second negative voltage side threshold voltage Vtnn. By applying the negative side write voltage Vwn to the second electrode 20, a high resistance state is realized on the negative voltage side, and data “1” is written to the selected cell.

When writing data “0” to the selected cell, the positive side write voltage Vwp is applied to the second electrode 20. The positive side write voltage Vwp is a voltage higher than the second positive voltage side threshold voltage Vtnp. By applying the positive side write voltage Vwp to the second electrode 20, a low resistance state is realized on the negative voltage side, and data “0” is written to the selected cell.

In the third operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the third operation example, when the data of the selected cell is data “1”, the application of the negative side read voltage Vrn does not destroy the data. In other words, in the case of the third operation example, non-destructive reading is possible if the data of the selected cell is data “1”.

On the other hand, when the data of the selected cell is data “0”, the application of the negative side read voltage Vrn lower than the first negative voltage side threshold voltage Vtpn may cause a current to flow. As a result, the data of the selected cell may change to data “1”. In other words, in the case of the third operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

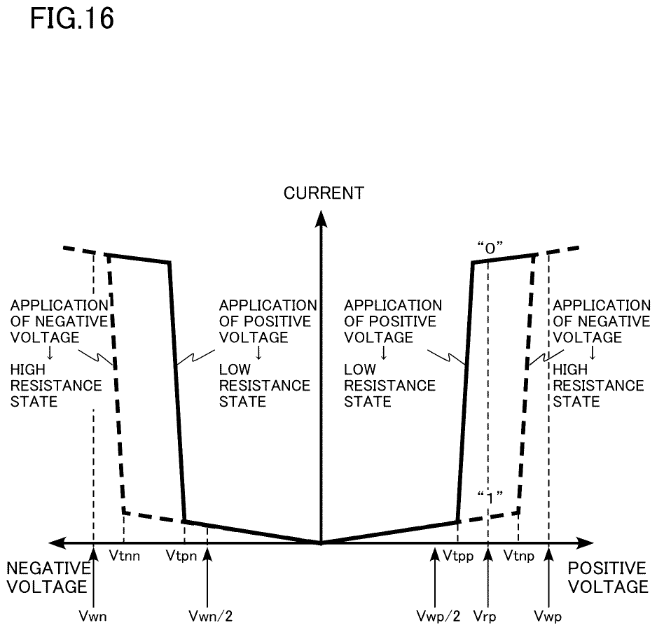

FIG. 16 is an explanatory diagram of a fourth operation example of the memory operation of the memory device according to the first modification example of the third embodiment. FIG. 16 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the fourth operation example, the high resistance state and the low resistance state on the positive voltage side are used for the memory operation. In the fourth operation example, the positive side read voltage Vrp is used as a read voltage.

When writing data “1” to the selected cell, the negative side write voltage Vwn is applied to the second electrode 20. The negative side write voltage Vwn is a voltage lower than the second negative voltage side threshold voltage Vtnn. By applying the negative side write voltage Vwn to the second electrode 20, a high resistance state is realized on the positive voltage side, and data “1” is written to the selected cell.

When writing data “O” to the selected cell, the positive side write voltage Vwp is applied to the second electrode 20. The positive side write voltage Vwp is a voltage higher than the second positive voltage side threshold voltage Vtnp. By applying the positive side write voltage Vwp to the second electrode 20, a low resistance state is realized on the positive voltage side, and data “0” is written to the selected cell.

In the fourth operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the fourth operation example, regardless of whether the data of the selected cell is data “1” or data “0”, the application of the positive side read voltage Vrp does not destroy the data. In other words, in the case of the fourth operation example, non-destructive reading is possible regardless of whether the data of the selected cell is data “1” or data “0”.

### Second Modification Example

A memory device according to a second modification example of the third embodiment is different from the memory device according to the third embodiment in that the current-voltage characteristics of the memory elements are different.

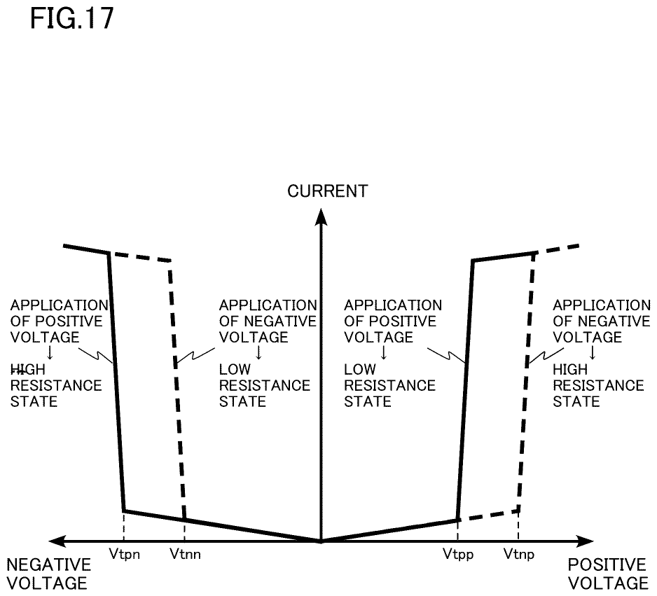

FIG. 17 is an explanatory diagram of the current-voltage characteristics of the memory element in the second modification example of the third embodiment. The horizontal axis indicates a voltage applied to the memory element, and the vertical axis indicates a current flowing through the memory element. In FIG. 17, the horizontal axis indicates a voltage applied to the second electrode 20 with the electric potential of the first electrode 10 as a reference. FIG. 17 shows the current-voltage characteristics of the memory layer 60 in the second modification example of the third embodiment. FIG. 17 shows the current-voltage characteristics of the memory cell MC in the second modification example of the third embodiment.

The memory element in the second modification example of the third embodiment shows different current-voltage characteristics when a predetermined positive voltage is applied to the second electrode 20 and when a predetermined negative voltage is applied to the second electrode 20. In FIG. 17, the solid line indicates the current-voltage characteristics when a predetermined positive voltage is applied to the second electrode 20, and the dotted line indicates the current-voltage characteristics when a predetermined negative voltage is applied to the second electrode 20.

When a predetermined positive voltage is applied to the second electrode 20, the current increases abruptly at a first positive voltage side threshold voltage Vtpp on the positive voltage side. In addition, when a predetermined positive voltage is applied to the second electrode 20, the current increases abruptly at a first negative voltage side threshold voltage Vtpn on the negative voltage side.

On the other hand, when a predetermined negative voltage is applied to the second electrode 20, the current increases abruptly at a second positive voltage side threshold voltage Vtnp on the positive voltage side. In addition, when a predetermined negative voltage is applied to the second electrode 20, the current increases abruptly at a second negative voltage side threshold voltage Vtnn on the negative voltage side.

The first positive voltage side threshold voltage Vtpp is lower than the second positive voltage side threshold voltage Vtnp. In addition, the first negative voltage side threshold voltage Vtpn is lower than the second negative voltage side threshold voltage Vtnn.

The memory element in the second modification example of the third embodiment can have a high resistance state and a low resistance state on both the positive voltage side and the negative voltage side. When a predetermined positive voltage is applied to the second electrode 20, a low resistance state is realized on the positive voltage side and a high resistance state is realized on the negative voltage side. On the other hand, when a predetermined negative voltage is applied to the second electrode 20, a high resistance state is realized on the positive voltage side and a low resistance state is realized on the negative voltage side. Hereinafter, the high resistance state will be defined as data “1”, and the low resistance state will be defined as data “0”. The memory cell MC can store 1-bit data of “0” and “1”.

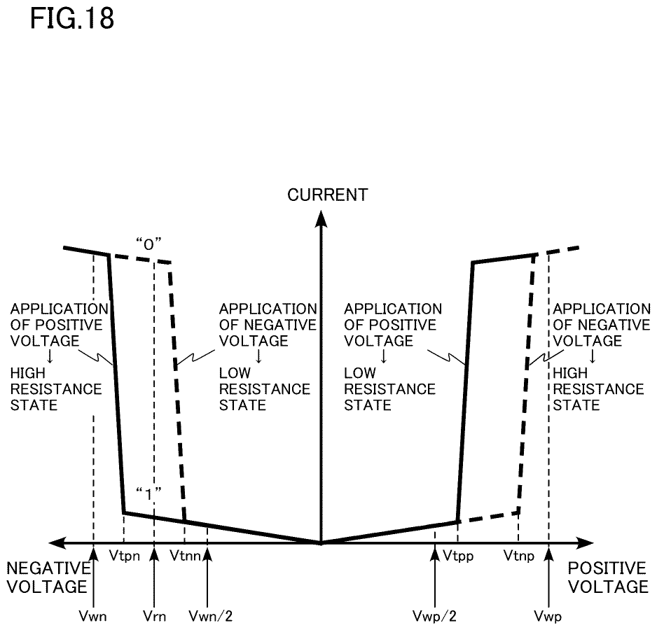

FIG. 18 is an explanatory diagram of a fifth operation example of the memory operation of the memory device according to the second modification example of the third embodiment. FIG. 18 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the fifth operation example, the high resistance state and the low resistance state on the negative voltage side are used for the memory operation. In the fifth operation example, the negative side read voltage Vrn is used as a read voltage.

When writing data “1” to the selected cell, the positive side write voltage Vwp is applied to the second electrode 20. The positive side write voltage Vwp is a voltage higher than the second positive voltage side threshold voltage Vtnp. By applying the positive side write voltage Vwp to the second electrode 20, a high resistance state is realized on the negative voltage side, and data “1” is written to the selected cell.

When writing data “O” to the selected cell, the negative side write voltage Vwn is applied to the second electrode 20. The negative side write voltage Vwn is a voltage lower than the first negative voltage side threshold voltage Vtpn. By applying the negative side write voltage Vwn to the second electrode 20, a low resistance state is realized on the negative voltage side, and data “0” is written to the selected cell.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the fifth operation example, regardless of whether the data of the selected cell is data “1” or data “0”, the application of the negative side read voltage Vrn does not destroy the data. In other words, in the case of the fifth operation example, non-destructive reading is possible regardless of whether the data of the selected cell is data “1” or data “0”.

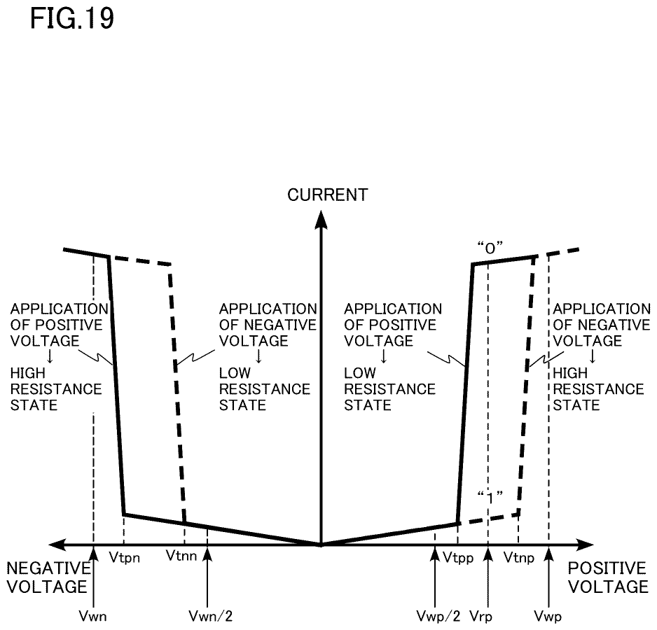

FIG. 19 is an explanatory diagram of a sixth operation example of the memory operation of the memory device according to the second modification example of the third embodiment. FIG. 19 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the third operation example, the high resistance state and low resistance state on the positive voltage side are used for memory operation. In the third operation example, the positive side read voltage Vrp is used as a read voltage.

When writing data “1” to the selected cell, the negative side write voltage Vwn is applied to the second electrode 20. The negative side write voltage Vwn is a voltage lower than the first negative voltage side threshold voltage Vtpn. By applying the negative side write voltage Vwn to the second electrode 20, a high resistance state is realized on the positive voltage side, and data “1” is written to the selected cell.

When writing data “O” to the selected cell, the positive side write voltage Vwp is applied to the second electrode 20. The positive side write voltage Vwp is a voltage higher than the second positive voltage side threshold voltage Vtnp. By applying the positive side write voltage Vwp to the second electrode 20, a low resistance state is realized on the positive voltage side, and data “0” is written to the selected cell.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the third operation example, regardless of whether the data of the selected cell is data “1” or data “0”, the application of the positive side read voltage Vrp does not destroy the data. In other words, in the case of the third operation example, non-destructive reading is possible regardless of whether the data of the selected cell is data “1” or data “0”.

### Third Modification Example

A memory device according to a third modification example of the third embodiment is different from the memory device according to the third embodiment in that the current-voltage characteristics of the memory elements are different.

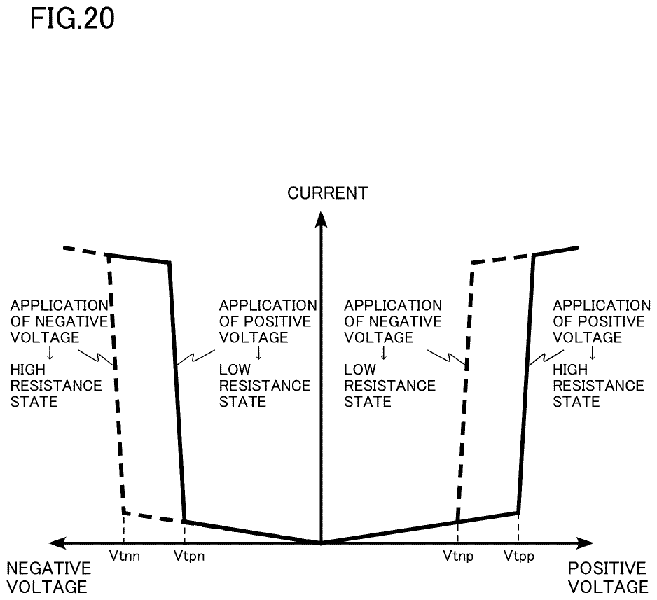

FIG. 20 is an explanatory diagram of the current-voltage characteristics of a memory element in the third modification example of the third embodiment. The horizontal axis indicates a voltage applied to the memory element, and the vertical axis indicates a current flowing through the memory element. In FIG. 20, the horizontal axis indicates a voltage applied to the second electrode 20 with the electric potential of the first electrode 10 as a reference. FIG. 20 shows the current-voltage characteristics of the memory layer 60 in the third modification example of the third embodiment. FIG. 20 shows the current-voltage characteristics of the memory cell MC in the third modification example of the third embodiment.

The memory element in the third modification example of the third embodiment shows different current-voltage characteristics when a predetermined positive voltage is applied to the second electrode 20 and when a predetermined negative voltage is applied to the second electrode 20. In FIG. 20, the solid line indicates the current-voltage characteristics when a predetermined positive voltage is applied to the second electrode 20, and the dotted line indicates the current-voltage characteristics when a predetermined negative voltage is applied to the second electrode 20.

When a predetermined positive voltage is applied to the second electrode 20, the current increases abruptly at a first positive voltage side threshold voltage Vtpp on the positive voltage side. In addition, when a predetermined positive voltage is applied to the second electrode 20, the current increases abruptly at a first negative voltage side threshold voltage Vtpn on the negative voltage side.

On the other hand, when a predetermined negative voltage is applied to the second electrode 20, the current increases abruptly at a second positive voltage side threshold voltage Vtnp on the positive voltage side. In addition, when a predetermined negative voltage is applied to the second electrode 20, the current increases abruptly at a second negative voltage side threshold voltage Vtnn on the negative voltage side.

The first positive voltage side threshold voltage Vtpp is higher than the second positive voltage side threshold voltage Vtnp. In addition, the first negative voltage side threshold voltage Vtpn is higher than the second negative voltage side threshold voltage Vtnn.

The memory element according to the third modification example of the third embodiment can have a high resistance state and a low resistance state on both the positive voltage side and the negative voltage side. When a predetermined positive voltage is applied to the second electrode 20, a high resistance state is realized on the positive voltage side and a low resistance state is realized on the negative voltage side. On the other hand, when a predetermined negative voltage is applied to the second electrode 20, a low resistance state is realized on the positive voltage side and a high resistance state is realized on the negative voltage side. Hereinafter, the high resistance state will be defined as data “1”, and the low resistance state will be defined as data “0”. The memory cell MC can store 1-bit data of “0” and “1”.

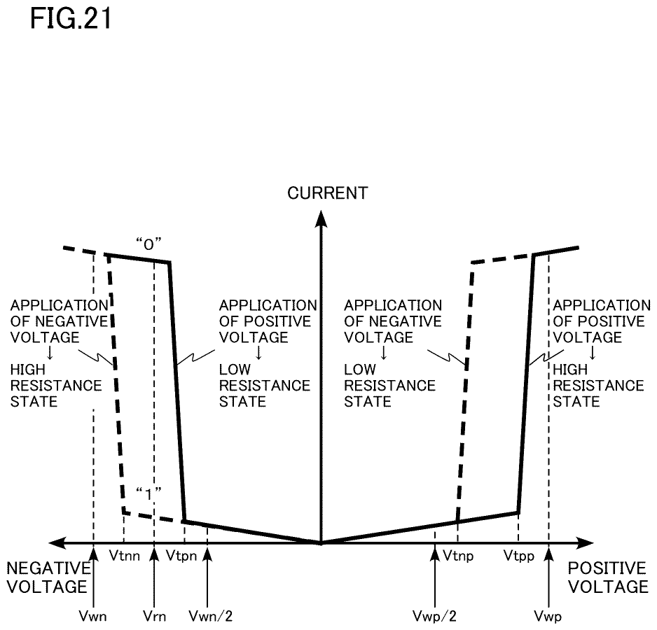

FIG. 21 is an explanatory diagram of a seventh operation example of the memory operation of the memory device according to the third modification example of the third embodiment. FIG. 21 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the seventh operation example, the high resistance state and the low resistance state on the negative voltage side are used for the memory operation. In the seventh operation example, the negative side read voltage Vrn is used as a read voltage.

When writing data “1” to the selected cell, the negative side write voltage Vwn is applied to the second electrode 20. The negative side write voltage Vwn is a voltage lower than the second negative voltage side threshold voltage Vtnn. By applying the negative side write voltage Vwn to the second electrode 20, a high resistance state is realized on the negative voltage side, and data “1” is written to the selected cell.

When writing data “O” to the selected cell, the positive side write voltage Vwp is applied to the second electrode 20. The positive side write voltage Vwp is a voltage higher than the first positive voltage side threshold voltage Vtpp. By applying the positive side write voltage Vwp to the second electrode 20, a low resistance state is realized on the negative voltage side, and data “0” is written to the selected cell.

In the seventh operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, in the seventh operation example, when writing data “0” to the selected cell, assuming that the data stored in the selected cell is data “1”, a current flows if the positive side write voltage Vwp is higher than the second positive voltage side threshold voltage Vtnp even if the positive side write voltage Vwp is lower than the first positive voltage side threshold voltage Vtpp. For this reason, data “0” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the seventh operation example, when the data of the selected cell is data “1”, the application of the negative side read voltage Vrn does not destroy the data. In other words, in the case of the seventh operation example, non-destructive reading is possible if the data of the selected cell is data “1”.

On the other hand, when the data of the selected cell is data “0”, the application of the negative side read voltage Vrn lower than the first negative voltage side threshold voltage Vtpn may cause a current to flow. As a result, the data of the selected cell may change to data “1”. In other words, in the case of the seventh operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

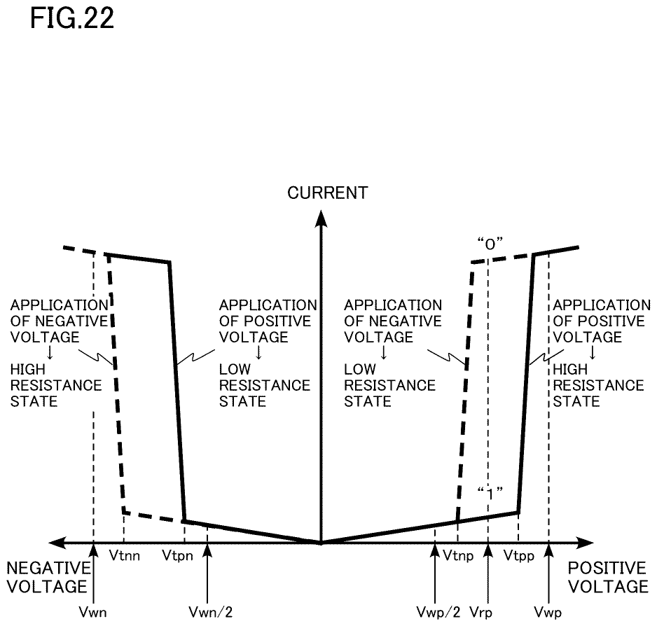

FIG. 22 is an explanatory diagram of an eighth operation example of the memory operation of the memory device according to the third modification example of the third embodiment. FIG. 22 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the eighth operation example, the high resistance state and the low resistance state on the positive voltage side are used for the memory operation. In the eighth operation example, the positive side read voltage Vrp is used as a read voltage.

When writing data “1” to the selected cell, the positive side write voltage Vwp is applied to the second electrode 20. The positive side write voltage Vwp is a voltage higher than the first positive voltage side threshold voltage Vtpp. By applying the positive side write voltage Vwp to the second electrode 20, a high resistance state is realized on the positive voltage side, and data “1” is written to the selected cell.

When writing data “O” to the selected cell, the negative side write voltage Vwn is applied to the second electrode 20. The negative side write voltage Vwn is a voltage lower than the second negative voltage side threshold voltage Vtnn. By applying the negative side write voltage Vwn to the second electrode 20, a low resistance state is realized on the positive voltage side, and data “0” is written to the selected cell.

In the eighth operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, in the eighth operation example, when writing data “0” to the selected cell, assuming that the data stored in the selected cell is data “1”, a current flows if the negative side write voltage Vwn is lower than the first negative voltage side threshold voltage Vtpn even if the negative side write voltage Vwn is higher than the second negative voltage side threshold voltage Vtnn. For this reason, data “0” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the eighth operation example, when the data of the selected cell is data “1”, the application of the positive side read voltage Vrp does not destroy the data. In other words, in the case of the eighth operation example, non-destructive reading is possible if the data of the selected cell is data “1”.

On the other hand, when the data of the selected cell is data “0”, the application of the positive side read voltage Vrp higher than the second positive voltage side threshold voltage Vtnp may cause a current to flow. As a result, the data of the selected cell may change to data “1”. In other words, in the case of the eighth operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

In the memory devices according to the third embodiment and its modification examples, the memory element of the memory cell MC has a switching function and an information storage function. The memory layer 60 is a single layer, and realizes the function of the switching layer 40 and the function of the variable resistance layer 50 in the first embodiment. Since the memory layer 60 in the third embodiment is a single layer and has a switching function and a memory function, the structure of the memory cell MC can be made very simple.

In addition, the first electrode 10, the second electrode 20, the first contact region 11, and the second contact region 21 of the memory device according to the third embodiment and its modification examples have the same configuration as the first electrode 10, the second electrode 20, the first contact region 11, and the second contact region 21 in the first embodiment. Therefore, according to the third embodiment and its modification examples, it is possible to realize a memory device having excellent characteristics as in the first embodiment.

In addition, the plurality of current-voltage characteristics of the memory elements shown in the third embodiment and its modification examples can be realized, for example, by adopting the memory layer 60 having an appropriate chemical composition.

### Fourth Embodiment

A memory device according to a fourth embodiment is different from the memory device according to the first embodiment in that the memory device according to the fourth embodiment further includes an insulating layer including a first layer and a second layer, a switching layer is provided between the first layer and the second layer in a second direction perpendicular to a first direction from a first electrode to a second electrode, the switching layer includes a first portion facing the first electrode, a second portion facing the first layer, and a third portion facing the second layer, and at least a part of the second electrode is provided between the second portion and the third portion in the second direction. Hereinafter, the description of a part of the content overlapping the first embodiment may be omitted.

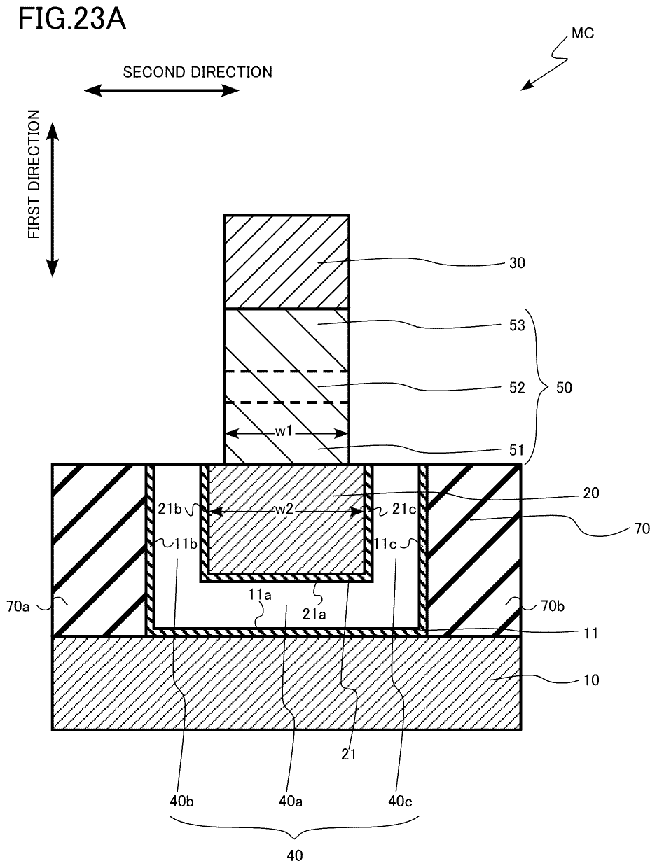

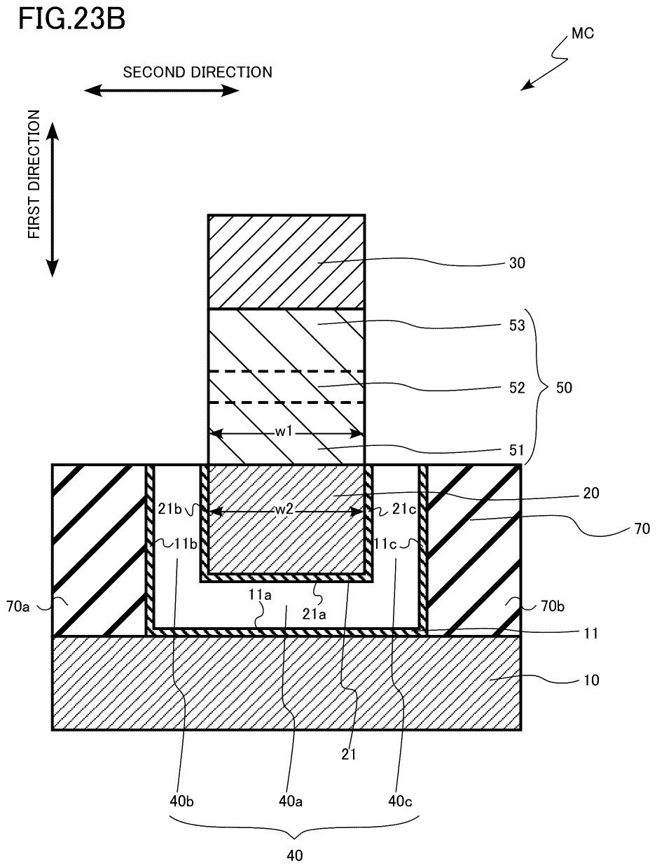

FIG. 23A is a schematic cross-sectional view of a memory cell of the memory device according to the fourth embodiment. FIG. 23A shows a cross section of one memory cell MC indicated by, for example, a dotted circle in the memory cell array 100 of FIG. 1.

As shown in FIG. 23A, the memory cell MC includes a first electrode 10, a second electrode 20, a third electrode 30, a switching layer 40, a variable resistance layer 50, and an interlayer insulating layer 70. In addition, as shown in FIG. 23, the memory cell MC includes a first contact region 11 and a second contact region 21.

The switching layer 40 includes a first portion 40a, a second portion 40b, and a third portion 40c. The first contact region 11 includes a first sub-region 11a, a second sub-region 11b, and a third sub-region 11c. The second contact region 21 includes a fourth sub-region 21a, a fifth sub-region 21b, and a sixth sub-region 21c. The interlayer insulating layer 70 includes a first layer 70a and a second layer 70b.

The interlayer insulating layer 70 is an example of an insulating layer. The first contact region 11 is an example of a region. The second contact region 21 is an example of a region.

The interlayer insulating layer 70 is provided on the first electrode 10. The interlayer insulating layer 70 includes the first layer 70a and the second layer 70b.

The second layer 70b of the interlayer insulating layer 70 is provided in the second direction perpendicular to the first direction from the first electrode 10 to the second electrode 20 with respect to the first layer 70a of the interlayer insulating layer 70.

The interlayer insulating layer 70 is an insulator. The interlayer insulating layer 70 is, for example, an oxide, a nitride, or an oxynitride. The interlayer insulating layer 70 contains, for example, silicon oxide. The interlayer insulating layer 70 is, for example, a silicon oxide layer.

The switching layer 40 is provided between the first layer 70a and the second layer 70b in the second direction.

The first portion 40a of the switching layer 40 faces the first electrode 10. The first portion 40a is provided between the first electrode 10 and the second electrode 20 in the first direction.

The second portion 40b of the switching layer 40 faces the first layer 70a. The second portion 40b is provided between the first layer 70a and the second electrode 20 in the second direction.

The third portion 40c of the switching layer 40 faces the second layer 70b. The third portion 40c is provided between the second layer 70b and the second electrode 20 in the second direction.

The first electrode 10 contains carbon (C). The second electrode 20 contains carbon (C).

At least a part of the second electrode 20 is provided between the second portion 40b of the switching layer 40 and the third portion 40c of the switching layer 40 in the second direction. At least a part of the second electrode 20 is provided between the first layer 70a and the second layer 70b in the second direction.

The first contact region 11 includes the first sub-region 11a, the second sub-region 11b, and the third sub-region 11c.

The first sub-region 11a is provided between the first electrode 10 and the first portion 40a in the first direction. The first sub-region 11a is in contact with, for example, the first electrode 10 and the first portion 40a.

The second sub-region 11b is provided between the first layer 70a and the second portion 40b in the second direction. The second sub-region 11b is in contact with, for example, the first layer 70a and the second portion 40b.

The third sub-region 11c is provided between the second layer 70b and the third portion 40c in the second direction. The third sub-region 11c is in contact with, for example, the second layer 70b and the third portion 40c.

The second contact region 21 includes the fourth sub-region 21a, the fifth sub-region 21b, and the sixth sub-region 21c.

The fourth sub-region 21a is provided between the first portion 40a and the second electrode 20 in the first direction. The fourth sub-region 21a is in contact with, for example, the first portion 40a and the second electrode 20.

The fifth sub-region 21b is provided between the second portion 40b and the second electrode 20 in the second direction. The fifth sub-region 21b is in contact with, for example, the second portion 40b and the second electrode 20.

The sixth sub-region 21c is provided between the third portion 40c and the second electrode 20 in the second direction. The sixth sub-region 21c is in contact with, for example, the third portion 40c and the second electrode 20.

The variable resistance layer 50 is provided on the second electrode 20. The variable resistance layer 50 is in contact with, for example, the second electrode 20.

The width (w1 in FIG. 23A) of the variable resistance layer 50 in the second direction is, for example, smaller than the width (w2 in FIG. 23A) of the second electrode 20 in the second direction.

FIG. 23B is a schematic cross-sectional view of a memory cell in a memory device according to other embodiment of the fourth embodiment. The width (w1 in FIG. 23B) of the variable resistance layer 50 in the second direction is, for example, equal to the width (w2 in FIG. 23B) of the second electrode 20 in the second direction.

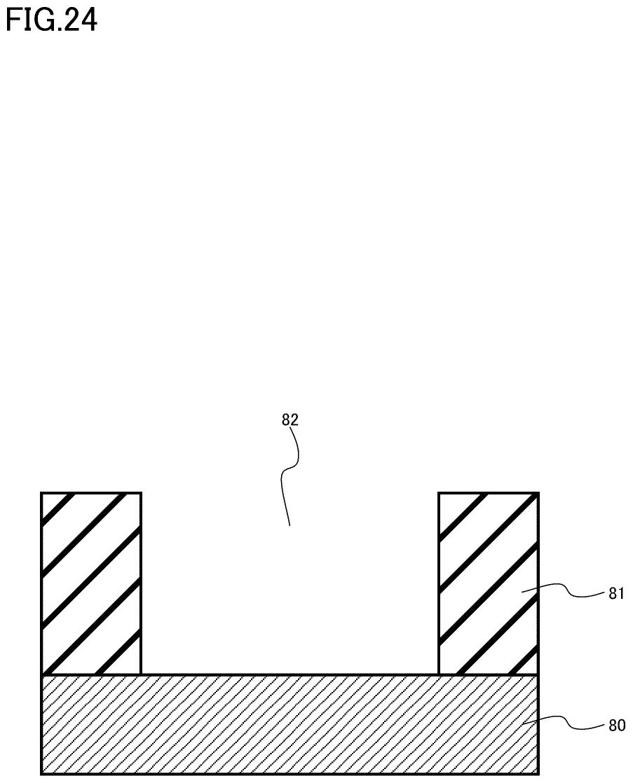

Then, an example of a method for manufacturing the memory device according to the fourth embodiment will be described. FIGS. 24 to 27 are schematic cross-sectional views showing an example of the method for manufacturing the memory device according to the fourth embodiment. FIGS. 24 to 27 are diagrams corresponding to FIG. 23A in the fourth embodiment. The memory device according to the fourth embodiment is formed by using a so-called damascene method.

First, a first carbon film 80 is formed on a substrate (not shown). The first carbon film 80 is formed by using, for example, a chemical vapor deposition method (CVD method). The first carbon film 80 finally becomes the first electrode 10.

Next, a silicon oxide film 81 is formed on the first carbon film 80. The silicon oxide film 81 is formed by using, for example, a CVD method. The silicon oxide film 81 finally becomes the interlayer insulating layer 70.

Then, a groove 82 is formed in the silicon oxide film 81 (FIG. 24). The first carbon film 80 is exposed at the bottom of the groove 82. The groove 82 is formed by using, for example, a photolithography method and a reactive ion etching method (RIE method).

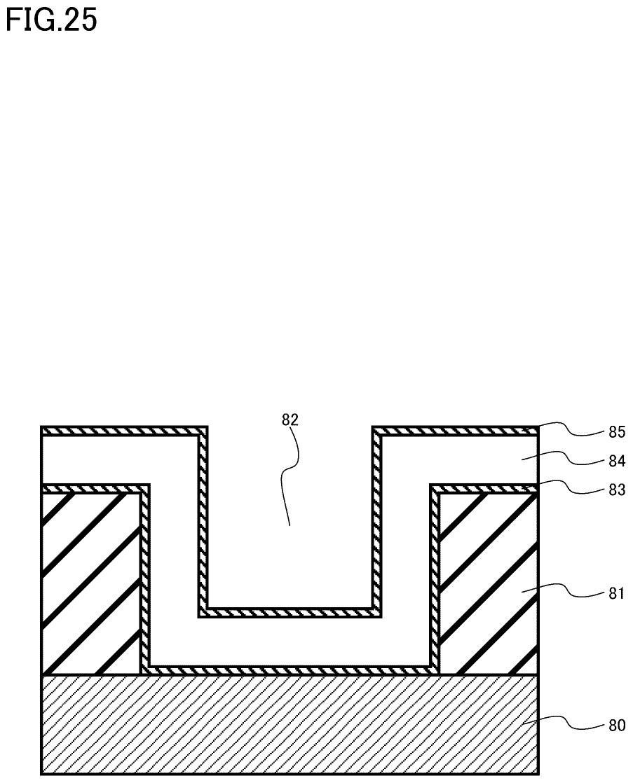

Then, a first titanium nitride film 83, a hafnium oxide film 84 containing zinc telluride, and a second titanium nitride film 85 are formed inside the groove 82 (FIG. 25). The first titanium nitride film 83, the hafnium oxide film 84 containing zinc telluride, and the second titanium nitride film 85 are formed by using, for example, a CVD method. The first titanium nitride film 83, the hafnium oxide film 84 containing zinc telluride, and the second titanium nitride film 85 finally become the first contact region 11, the switching layer 40, and the second contact region 21, respectively.

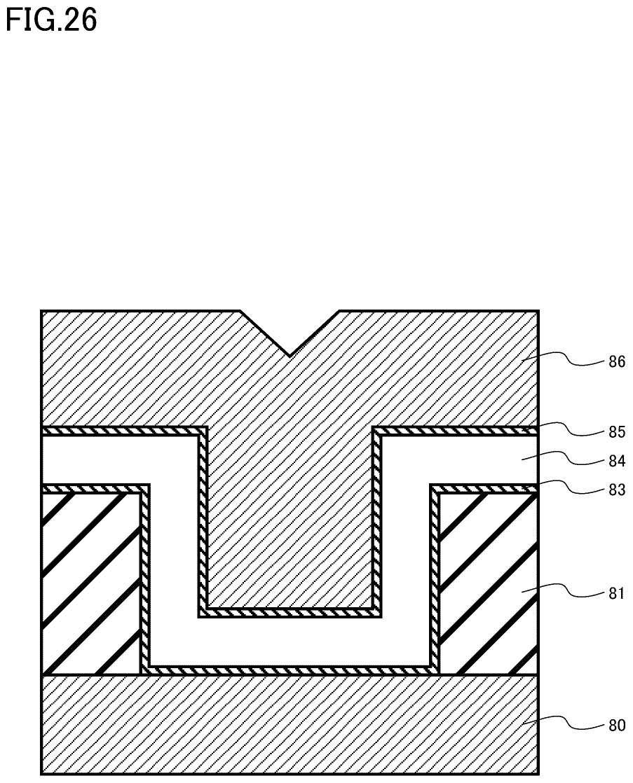

Then, a second carbon film 86 is formed inside the groove 82 (FIG. 26). The second carbon film 86 is formed by using, for example, a CVD method. The second carbon film 86 finally becomes the second electrode 20.

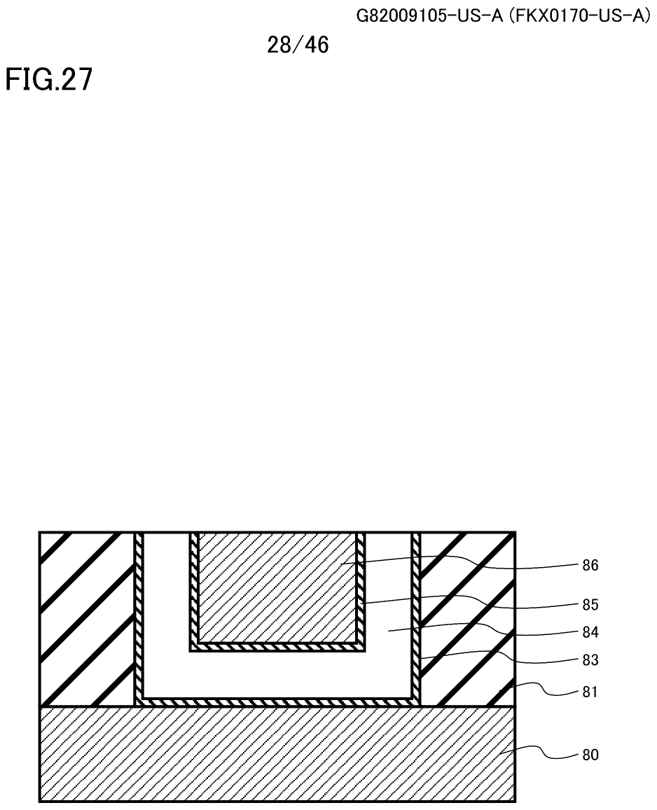

Then, the first titanium nitride film 83, the hafnium oxide film 84 containing zinc telluride, the second titanium nitride film 85, and the second carbon film 86 on the silicon oxide film 81 are removed (FIG. 27). The first titanium nitride film 83, the hafnium oxide film 84 containing zinc telluride, the second titanium nitride film 85, and the second carbon film 86 are removed by using, for example, a chemical mechanical polishing method (CMP method). The first titanium nitride film 83, the hafnium oxide film 84 containing zinc telluride, the second titanium nitride film 85, and the second carbon film 86 remain inside the groove 82.

Then, the variable resistance layer 50 and the third electrode 30 are formed on the second carbon film 86 using a known process technology, thereby manufacturing the memory device according to the fourth embodiment shown in FIG. 23A.

According to the fourth embodiment and the other embodiment of the fourth embodiment, as in the first embodiment, it is possible to realize a switching element in which film peeling between the first electrode 10 and the switching layer 40 and film peeling between the second electrode 20 and the switching layer 40 are suppressed.

### First Modification Example

A memory device according to a first modification example of the fourth embodiment is different from the memory device according to the fourth embodiment in that the memory device according to the first modification example of the fourth embodiment does not include the second contact region.

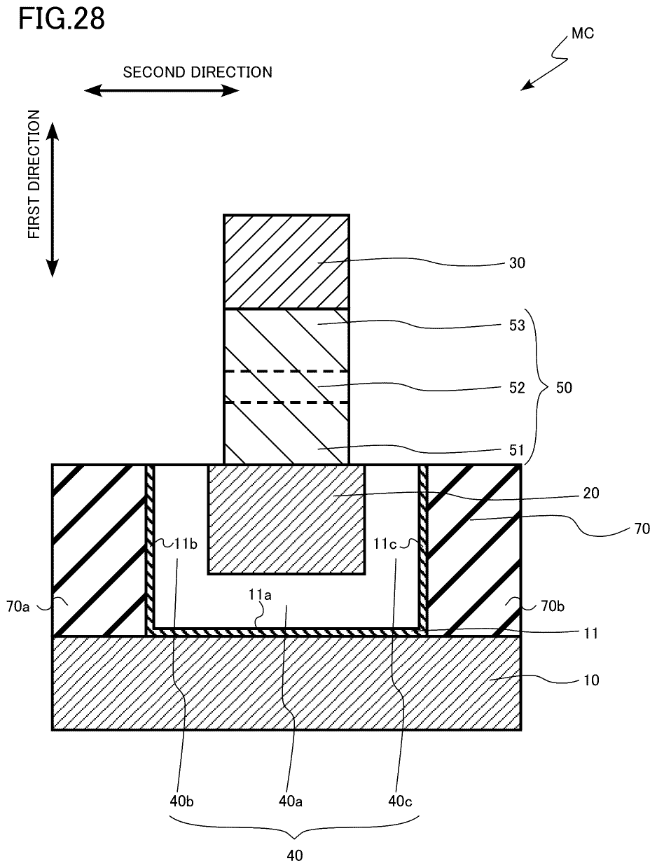

FIG. 28 is a schematic cross-sectional view of a memory cell of the memory device according to the first modification example of the fourth embodiment. FIG. 28 is a diagram corresponding to FIG. 23A in the fourth embodiment.

As shown in FIG. 28, a memory cell MC includes a first electrode 10, a second electrode 20, a third electrode 30, a switching layer 40, a variable resistance layer 50, and an interlayer insulating layer 70. In addition, as shown in FIG. 28, the memory cell MC includes a first contact region 11. The memory cell MC does not include the second contact region 21.

According to the first modification example of the fourth embodiment, it is possible to realize a switching element in which film peeling between the first electrode 10 and the switching layer 40 is suppressed.

### Second Modification Example

A memory device according to a second modification example of the fourth embodiment is different from the memory device according to the fourth embodiment in that the memory device according to the second modification example of the fourth embodiment does not include the first contact region.

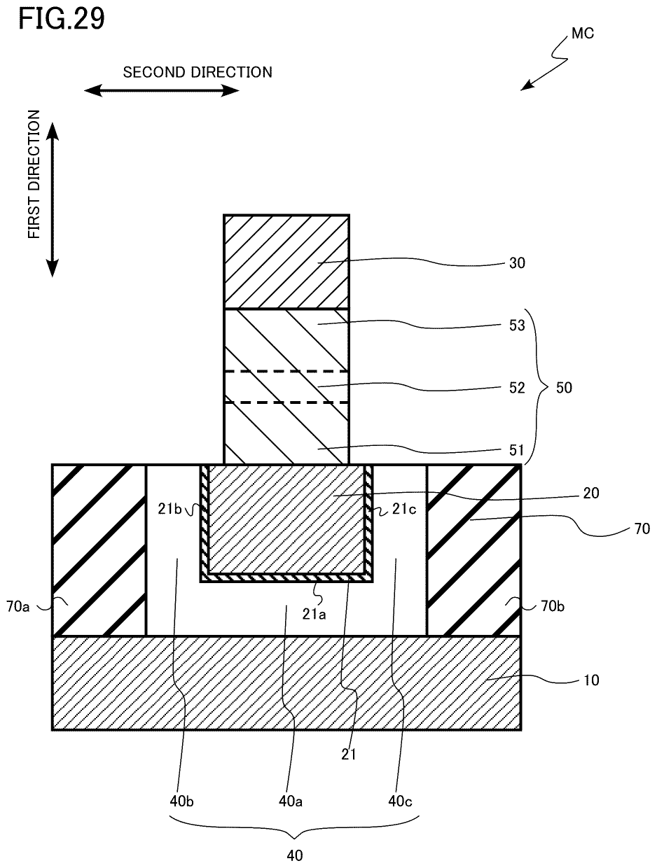

FIG. 29 is a schematic cross-sectional view of a memory cell of the memory device according to the second modification example of the fourth embodiment. FIG. 29 is a diagram corresponding to FIG. 23A in the fourth embodiment.

As shown in FIG. 29, a memory cell MC includes a first electrode 10, a second electrode 20, a third electrode 30, a switching layer 40, a variable resistance layer 50, and an interlayer insulating layer 70. In addition, as shown in FIG. 29, the memory cell MC includes a second contact region 21. The memory cell MC does not include the first contact region 11.

According to the memory device according to the second modification example of the fourth embodiment, it is possible to realize a switching element in which film peeling between the second electrode 20 and the switching layer 40 is suppressed.

### Third Modification Example

A memory device according to a third modification example of the fourth embodiment is different from the memory device according to the fourth embodiment in that the memory device according to the third modification example of the fourth embodiment does not include the second contact region and the first contact region does not include the second sub-region and the third sub-region.

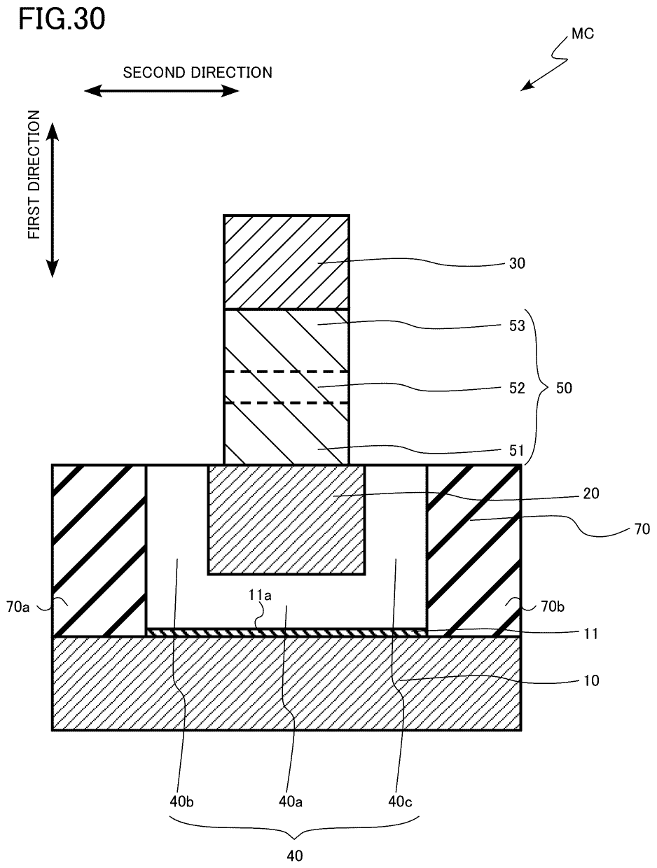

FIG. 30 is a schematic cross-sectional view of a memory cell of a memory device according to a third modification example of the fourth embodiment. FIG. 30 is a diagram corresponding to FIG. 23A in the fourth embodiment.

As shown in FIG. 30, a memory cell MC includes a first electrode 10, a second electrode 20, a third electrode 30, a switching layer 40, a variable resistance layer 50, and an interlayer insulating layer 70. In addition, as shown in FIG. 30, the memory cell MC includes a first contact region 11. The first contact region 11 does not include the second sub-region 11b and the third sub-region 11c. In addition, the memory cell MC does not include the second contact region 21.

According to the third modification example of the fourth embodiment, it is possible to realize a switching element in which film peeling between the first electrode 10 and the switching layer 40 is suppressed.

### Fourth Modification Example

A memory device according to a fourth modification example of the fourth embodiment is different from the memory device according to the fourth embodiment in that the memory device according to the fourth modification example of the fourth embodiment does not include the first contact region and the second contact region does not include the fifth sub-region and the sixth sub-region.

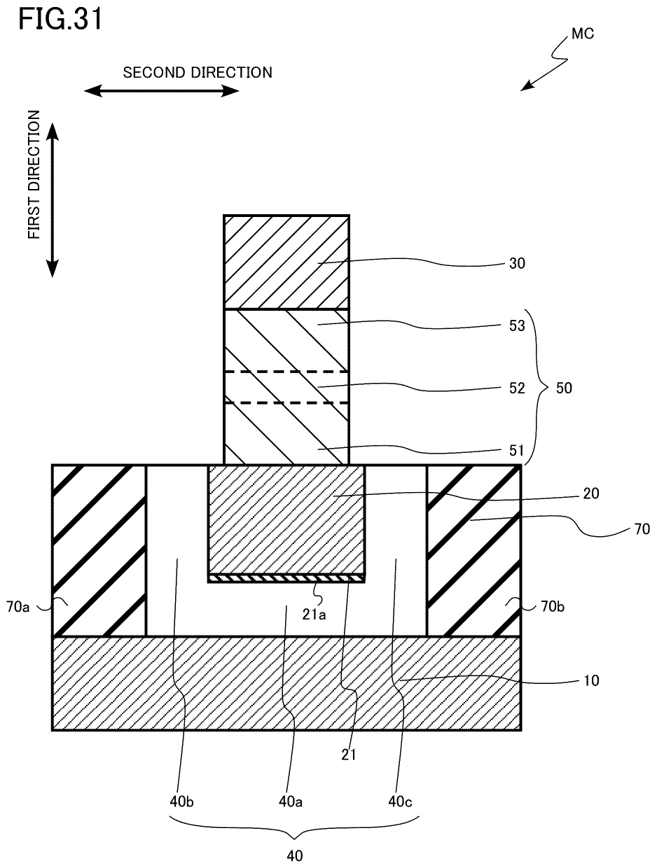

FIG. 31 is a schematic cross-sectional view of a memory cell of the memory device according to the fourth modification example of the fourth embodiment. FIG. 31 is a diagram corresponding to FIG. 23A in the fourth embodiment.

As shown in FIG. 31, a memory cell MC includes a first electrode 10, a second electrode 20, a third electrode 30, a switching layer 40, a variable resistance layer 50, and an interlayer insulating layer 70. In addition, as shown in FIG. 31, the memory cell MC includes a second contact region 21. The second contact region 21 does not include the fifth sub-region 21b and the sixth sub-region 21c. In addition, the memory cell MC does not include the first contact region 11.

According to the fourth modification example of the fourth embodiment, it is possible to realize a switching element in which film peeling between the second electrode 20 and the switching layer 40 is suppressed.

### Fifth Modification Example

A memory device according to a fifth modification example of the fourth embodiment is different from the memory device according to the fourth embodiment in that the first contact region does not include the second sub-region and the third sub-region and the second contact region does not include the fifth sub-region and the sixth sub-region.

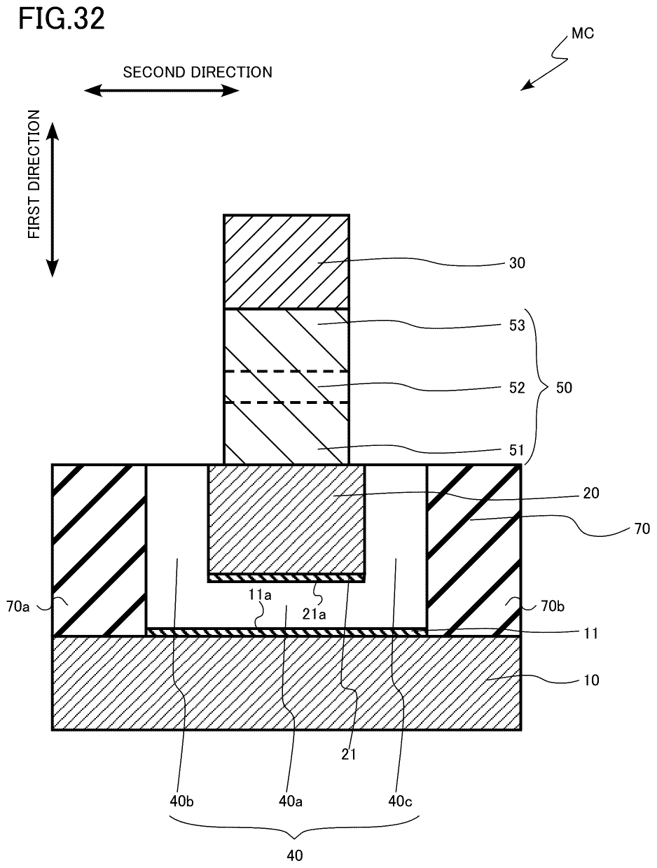

FIG. 32 is a schematic cross-sectional view of a memory cell of the memory device according to the fifth modification example of the fourth embodiment. FIG. 32 is a diagram corresponding to FIG. 23A in the fourth embodiment.

As shown in FIG. 32, a memory cell MC includes a first electrode 10, a second electrode 20, a third electrode 30, a switching layer 40, a variable resistance layer 50, and an interlayer insulating layer 70. In addition, as shown in FIG. 32, the memory cell MC includes a first contact region 11 and a second contact region 21. The first contact region 11 does not include the second sub-region 11b and the third sub-region 11c. In addition, the second contact region 21 does not include the fifth sub-region 21b and the sixth sub-region 21c.

According to the fifth modification example of the fourth embodiment, it is possible to realize a switching element in which film peeling between the first electrode 10 and the switching layer 40 and film peeling between the second electrode 20 and the switching layer 40 are suppressed.

### Sixth Modification Example

A memory device according to a sixth modification example of the fourth embodiment is different from the memory device according to the fourth embodiment in that the first contact region does not include the second sub-region and the third sub-region.

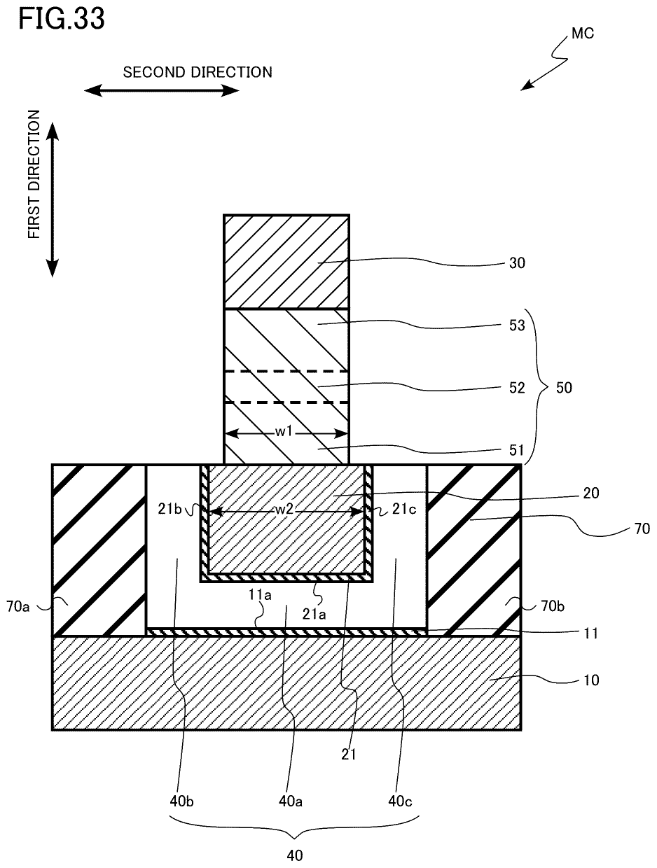

FIG. 33 is a schematic cross-sectional view of a memory cell of the memory device according to the sixth modification example of the fourth embodiment. FIG. 33 is a diagram corresponding to FIG. 23A in the fourth embodiment.

As shown in FIG. 33, a memory cell MC includes a first electrode 10, a second electrode 20, a third electrode 30, a switching layer 40, a variable resistance layer 50, and an interlayer insulating layer 70. In addition, as shown in FIG. 33, the memory cell MC includes a first contact region 11 and a second contact region 21. The first contact region 11 does not include the second sub-region 11b and the third sub-region 11c.

According to the memory device according to the sixth modification example of the fourth embodiment, it is possible to realize a switching element in which film peeling between the first electrode 10 and the switching layer 40 and film peeling between the second electrode 20 and the switching layer 40 are suppressed.

As described above, according to the fourth embodiment and its modification examples, as in the first embodiment, it is possible to realize a switching element in which film peeling between the first electrode 10 and the switching layer 40 and film peeling between the second electrode 20 and the switching layer 40 are suppressed. Therefore, it is possible to realize a memory device with excellent characteristics.

### Fifth Embodiment

A memory device according to a fifth embodiment is different from the memory device according to the fourth embodiment in that a part of the switching layer is provided in the first direction of the first layer and another part of the switching layer is provided in the first direction of the second layer. Hereinafter, the description of a part of the content overlapping the first or fourth embodiment may be omitted.

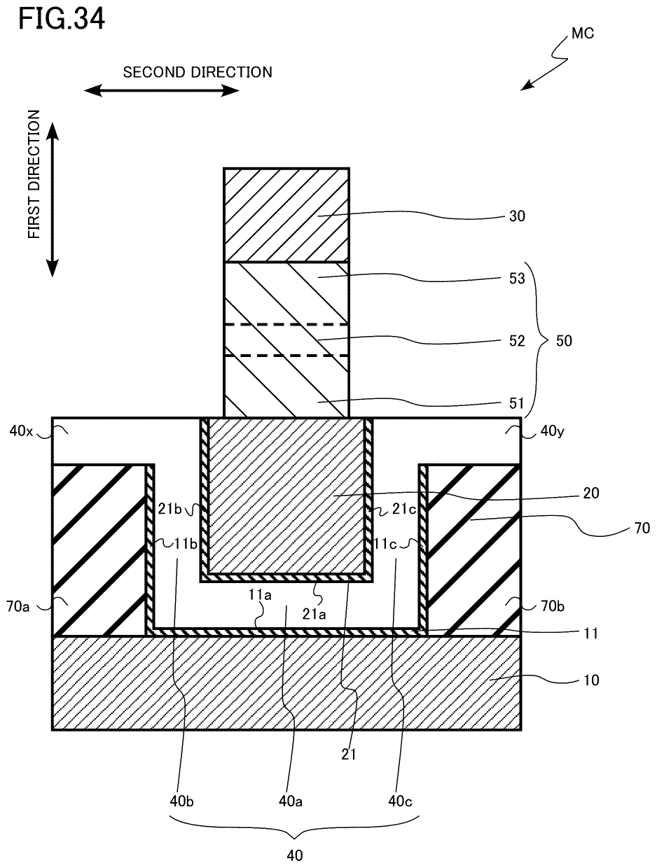

FIG. 34 is a schematic cross-sectional view of a memory cell of the memory device according to the fifth embodiment. FIG. 34 shows a cross section of one memory cell MC indicated by, for example, a dotted circle in the memory cell array 100 of FIG. 1.

As shown in FIG. 34, the memory cell MC includes a first electrode 10, a second electrode 20, a third electrode 30, a switching layer 40, a variable resistance layer 50, and an interlayer insulating layer 70. In addition, as shown in FIG. 34, the memory cell MC includes a first contact region 11 and a second contact region 21.

The switching layer 40 includes a first portion 40a, a second portion 40b, and a third portion 40c. The first contact region 11 includes a first sub-region 11a, a second sub-region 11b, and a third sub-region 11c. The second contact region 21 includes a fourth sub-region 21a, a fifth sub-region 21b, and a sixth sub-region 21c. The interlayer insulating layer 70 includes a first layer 70a and a second layer 70b.

The interlayer insulating layer 70 is an example of an insulating layer. The first contact region 11 is an example of a region. The second contact region 21 is an example of a region.

The interlayer insulating layer 70 is provided on the first electrode 10. The interlayer insulating layer 70 includes the first layer 70a and the second layer 70b.

A part 40x of the switching layer 40 is provided in the first direction of the first layer 70a. The part 40x of the switching layer 40 is provided on the first layer 70a. The part 40x of the switching layer 40 is in contact with, for example, the first layer 70a.

Another part 40y of the switching layer 40 is provided in the first direction of the second layer 70b. Another part 40y of the switching layer 40 is provided on the second layer 70b. Another part 40y of the switching layer 40 is in contact with, for example, the second layer 70b.

According to the fifth embodiment, as in the first embodiment, it is possible to realize a switching element in which film peeling between the first electrode 10 and the switching layer 40 and film peeling between the second electrode 20 and the switching layer 40 are suppressed.

### First Modification Example

A memory device according to a first modification example of the fifth embodiment is different from the memory device according to the fifth embodiment in that the memory device according to the first modification example of the fifth embodiment does not include the second contact region.

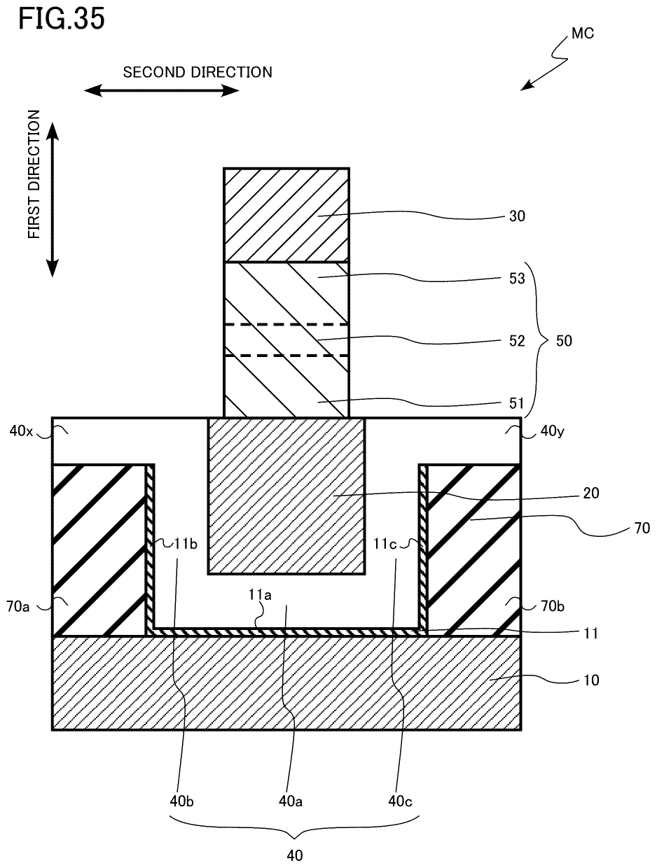

FIG. 35 is a schematic cross-sectional view of a memory cell of the memory device according to the first modification example of the fifth embodiment. FIG. 35 is a diagram corresponding to FIG. 34 in the fifth embodiment.

As shown in FIG. 35, a memory cell MC includes a first electrode 10, a second electrode 20, a third electrode 30, a switching layer 40, a variable resistance layer 50, and an interlayer insulating layer 70. In addition, as shown in FIG. 35, the memory cell MC includes a first contact region 11. The memory cell MC does not include the second contact region 21.

According to the first modification example of the fifth embodiment, it is possible to realize a switching element in which film peeling between the first electrode 10 and the switching layer 40 is suppressed.

### Second Modification Example

A memory device according to a second modification example of the fifth embodiment is different from the memory device according to the fifth embodiment in that the memory device according to the second modification example of the fifth embodiment does not include the first contact region.

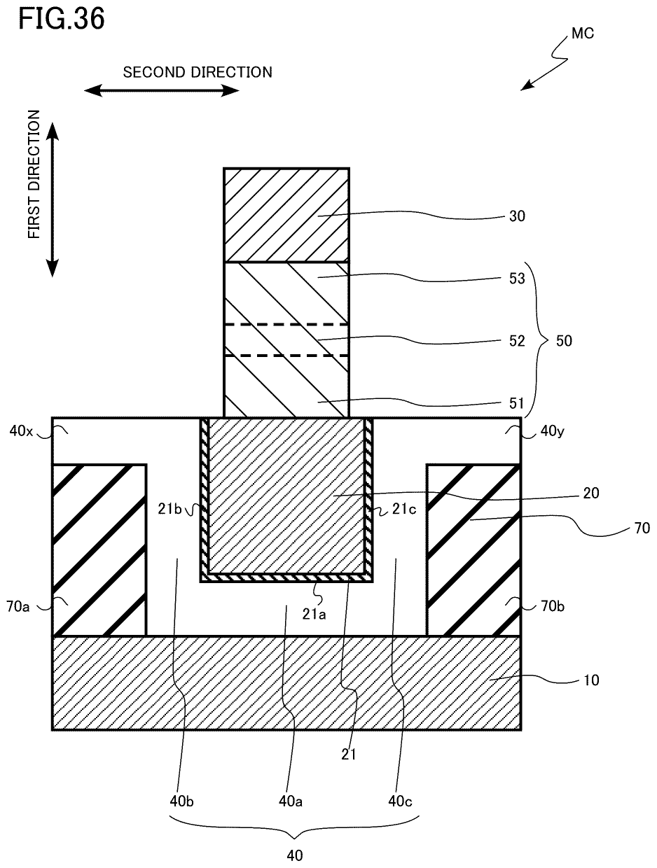

FIG. 36 is a schematic cross-sectional view of a memory cell of the memory device according to the second modification example of the fifth embodiment. FIG. 36 is a diagram corresponding to FIG. 34 in the fifth embodiment.

As shown in FIG. 36, a memory cell MC includes a first electrode 10, a second electrode 20, a third electrode 30, a switching layer 40, a variable resistance layer 50, and an interlayer insulating layer 70. In addition, as shown in FIG. 36, the memory cell MC includes a second contact region 21. The memory cell MC does not include the first contact region 11.

According to the second modification example of the fifth embodiment, it is possible to realize a switching element in which film peeling between the second electrode 20 and the switching layer 40 is suppressed.

### Third Modification Example

A memory device according to a third modification example of the fifth embodiment is different from the memory device according to the fifth embodiment in that the memory device according to the third modification example of the fifth embodiment does not include the second contact region and the first contact region does not include the second sub-region and the third sub-region.

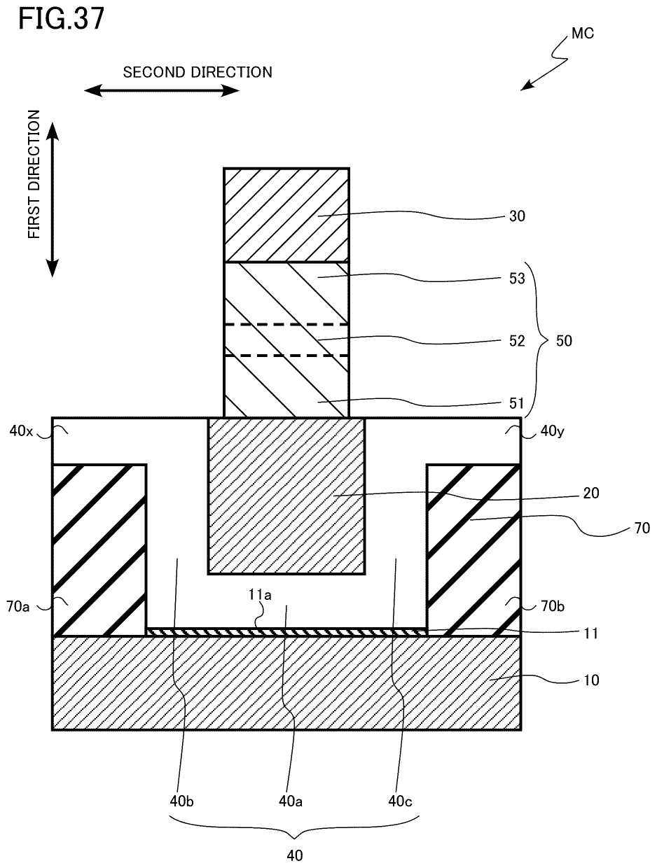

FIG. 37 is a schematic cross-sectional view of a memory cell of the memory device according to the third modification example of the fifth embodiment. FIG. 37 is a diagram corresponding to FIG. 34 in the fifth embodiment.

As shown in FIG. 37, a memory cell MC includes a first electrode 10, a second electrode 20, a third electrode 30, a switching layer 40, a variable resistance layer 50, and an interlayer insulating layer 70. In addition, as shown in FIG. 37, the memory cell MC includes a first contact region 11. The first contact region 11 does not include the second sub-region 11b and the third sub-region 11c. In addition, the memory cell MC does not include the second contact region 21.

According to the third modification example of the fifth embodiment, it is possible to realize a switching element in which film peeling between the first electrode 10 and the switching layer 40 is suppressed.

### Fourth Modification Example

A memory device according to a fourth modification example of the fifth embodiment is different from the memory device according to the fifth embodiment in that the memory device according to the fourth modification example of the fifth embodiment does not include the first contact region and the second contact region does not include the fifth sub-region and the sixth sub-region.

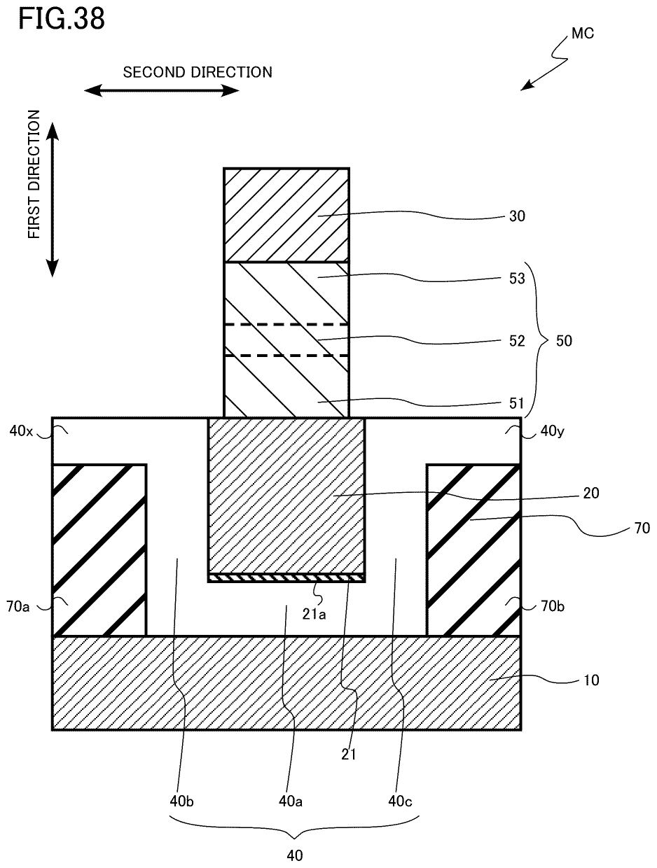

FIG. 38 is a schematic cross-sectional view of a memory cell of the memory device according to the fourth modification example of the fifth embodiment. FIG. 38 is a diagram corresponding to FIG. 34 in the fifth embodiment.

As shown in FIG. 38, a memory cell MC includes a first electrode 10, a second electrode 20, a third electrode 30, a switching layer 40, a variable resistance layer 50, and an interlayer insulating layer 70. In addition, as shown in FIG. 38, the memory cell MC includes a second contact region 21. The second contact region 21 does not include the fifth sub-region 21b and the sixth sub-region 21c. In addition, the memory cell MC does not include the first contact region 11.

According to the fourth modification example of the fifth embodiment, it is possible to realize a switching element in which film peeling between the second electrode 20 and the switching layer 40 is suppressed.

### Fifth Modification Example

A memory device according to a fifth modification example of the fifth embodiment is different from the memory device according to the fifth embodiment in that the first contact region does not include the second sub-region and the third sub-region and the second contact region does not include the fifth sub-region and the sixth sub-region.

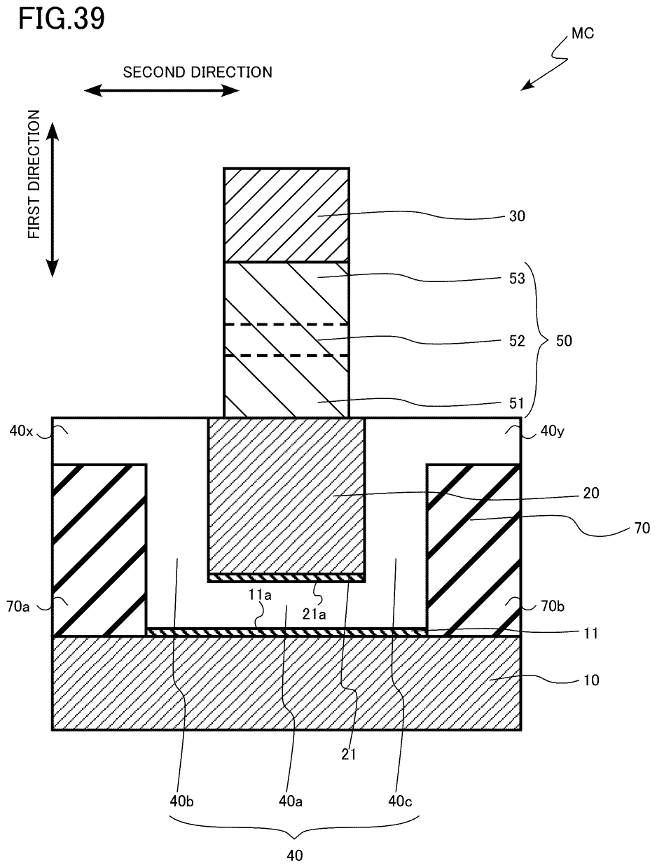

FIG. 39 is a schematic cross-sectional view of a memory cell of the memory device according to the fifth modification example of the fifth embodiment. FIG. 39 is a diagram corresponding to FIG. 34 in the fourth embodiment.

As shown in FIG. 39, a memory cell MC includes a first electrode 10, a second electrode 20, a third electrode 30, a switching layer 40, a variable resistance layer 50, and an interlayer insulating layer 70. In addition, as shown in FIG. 39, the memory cell MC includes a first contact region 11 and a second contact region 21. The first contact region 11 does not include the second sub-region 11b and the third sub-region 11c. In addition, the second contact region 21 does not include the fifth sub-region 21b and the sixth sub-region 21c.

According to the fifth modification example of the fifth embodiment, it is possible to realize a switching element in which film peeling between the first electrode 10 and the switching layer 40 and film peeling between the second electrode 20 and the switching layer 40 are suppressed.

### Sixth Modification Example

A memory device according to a sixth modification example of the fifth embodiment is different from the memory device according to the fifth embodiment in that the first contact region does not include the second sub-region and the third sub-region.

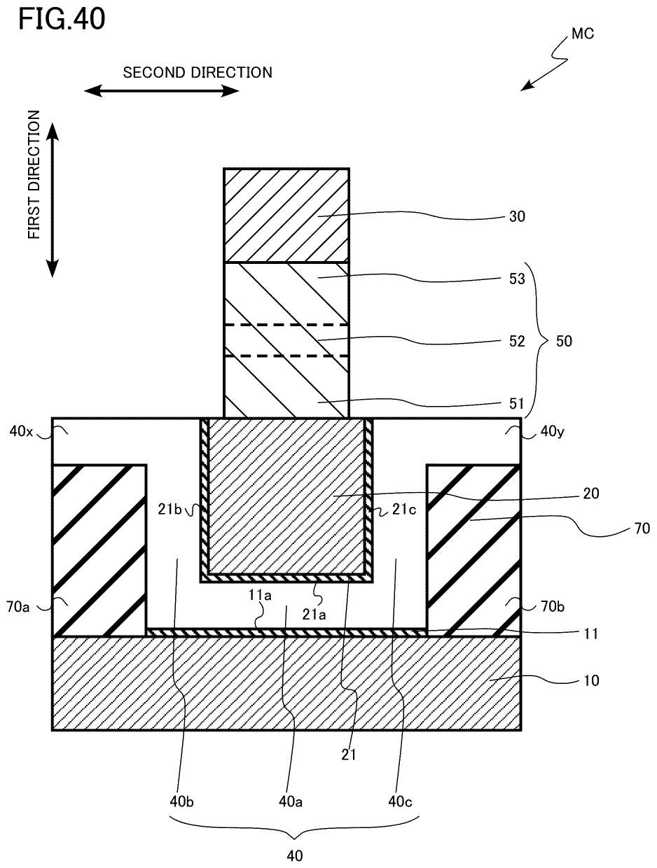

FIG. 40 is a schematic cross-sectional view of a memory cell of the memory device according to the sixth modification example of the fifth embodiment. FIG. 40 is a diagram corresponding to FIG. 34 in the fifth embodiment.

As shown in FIG. 40, a memory cell MC includes a first electrode 10, a second electrode 20, a third electrode 30, a switching layer 40, a variable resistance layer 50, and an interlayer insulating layer 70. In addition, as shown in FIG. 40, the memory cell MC includes a first contact region 11 and a second contact region 21. The first contact region 11 does not include the second sub-region 11b and the third sub-region 11c.

According to the sixth modification example of the fifth embodiment, it is possible to realize a switching element in which film peeling between the first electrode 10 and the switching layer 40 and film peeling between the second electrode 20 and the switching layer 40 are suppressed.

As described above, according to the fifth embodiment and its modification examples, as in the first embodiment, it is possible to realize a switching element in which film peeling between the first electrode 10 and the switching layer 40, and film peeling between the second electrode 20 and the switching layer 40 are suppressed. Therefore, it is possible to realize a memory device with excellent characteristics.

### Sixth Embodiment

A memory device according to a sixth embodiment is different from the memory device according to the first embodiment in that the memory device according to the sixth embodiment further includes an insulating layer including a first layer and a second layer, a switching layer is provided between the first layer and the second layer in a second direction perpendicular to a first direction from a first electrode to a second electrode, and the width of the second electrode in the second direction is larger than the width of the switching layer between the first layer and the second layer in the second direction. Hereinafter, the description of a part of the content overlapping the first embodiment may be omitted.

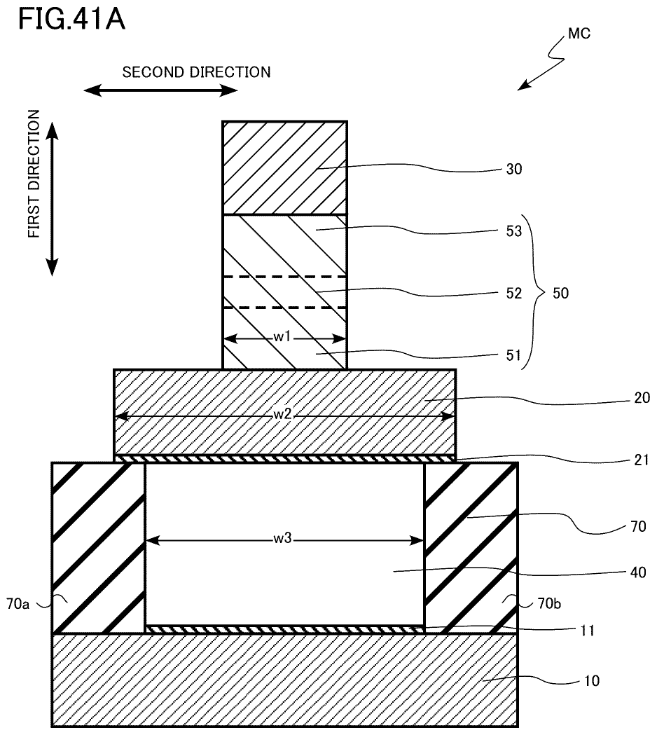

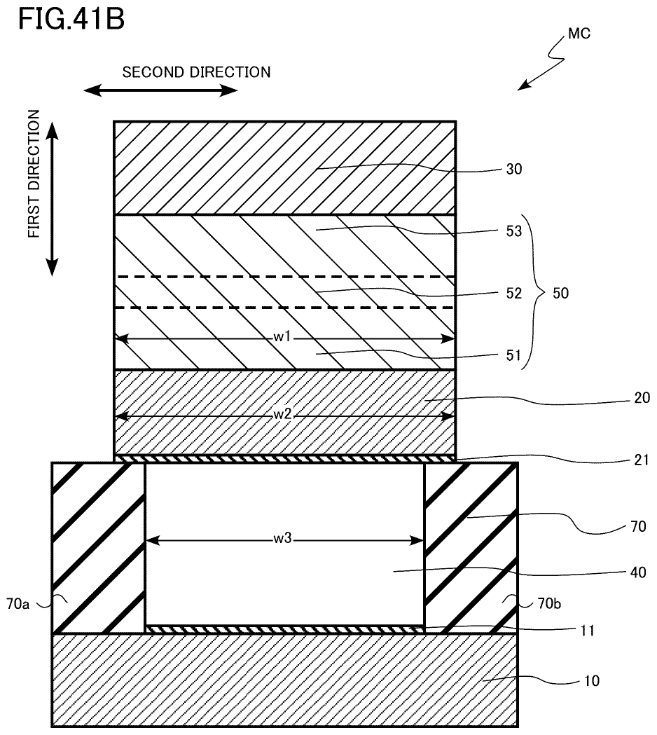

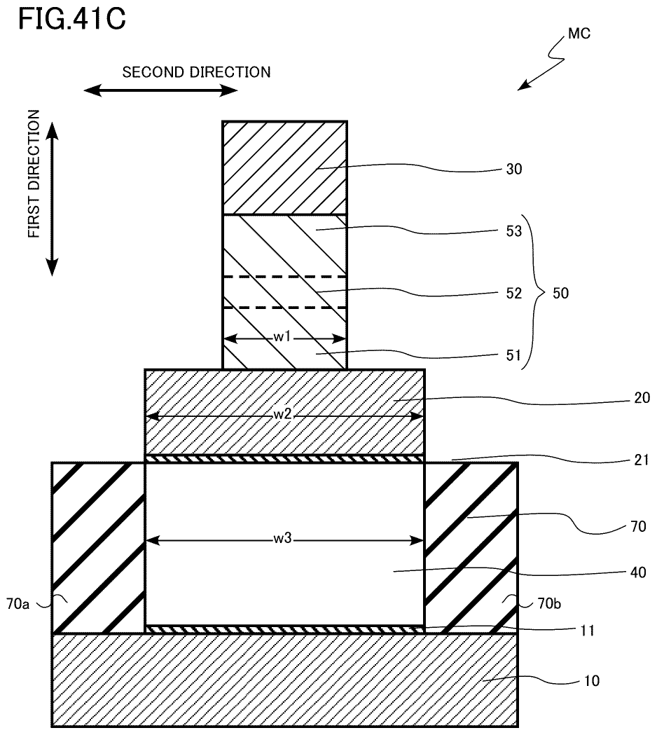

FIG. 41A is a schematic cross-sectional view of a memory cell of the memory device according to the sixth embodiment. FIG. 41 shows a cross section of one memory cell MC indicated by, for example, a dotted circle in the memory cell array 100 of FIG. 1.

As shown in FIG. 41A, the memory cell MC includes a first electrode 10, a second electrode 20, a third electrode 30, a switching layer 40, a variable resistance layer 50, and an interlayer insulating layer 70. In addition, as shown in FIG. 41A, the memory cell MC includes a first contact region 11 and a second contact region 21.

The interlayer insulating layer 70 includes a first layer 70a and a second layer 70b.

The interlayer insulating layer 70 is an example of an insulating layer. The first contact region 11 is an example of a region. The second contact region 21 is an example of a region.

The interlayer insulating layer 70 is provided on the first electrode 10. The interlayer insulating layer 70 includes the first layer 70a and the second layer 70b.

The second layer 70b of the interlayer insulating layer 70 is provided in the second direction perpendicular to the first direction from the first electrode 10 to the second electrode 20 with respect to the first layer 70a of the interlayer insulating layer 70.

The interlayer insulating layer 70 is an insulator. The interlayer insulating layer 70 is, for example, an oxide, a nitride, or an oxynitride. The interlayer insulating layer 70 contains, for example, silicon oxide. The interlayer insulating layer 70 is, for example, a silicon oxide layer.

The switching layer 40 is provided between the first layer 70a and the second layer 70b in the second direction.

The first electrode 10 contains carbon (C). The second electrode 20 contains carbon (C).

The variable resistance layer 50 is provided on the second electrode 20. The variable resistance layer 50 is in contact with, for example, the second electrode 20.

The width (w1 in FIG. 41A) of the variable resistance layer 50 in the second direction is, for example, smaller than the width (w2 in FIG. 41A) of the second electrode 20 in the second direction.

FIG. 41B is a schematic cross-sectional view of a memory cell in a memory device according to a first other embodiment of the sixth embodiment. The width (w1 in FIG. 41B) of the variable resistance layer 50 in the second direction is, for example, equal to the width (w2 in FIG. 41B) of the second electrode 20 in the second direction.

As shown in FIG. 41A, the width in the second direction of the second electrode 20 (w2 in FIG. 41A) is, for example, larger than the width in the second direction of the switching layer 40 (w3 in FIG. 41A) provided between the first layer 70a and the second layer 70b.

FIG. 41C is a schematic cross-sectional view of a memory cell in a memory device according to a second other embodiment of the sixth embodiment. The width (w2 in FIG. 41C) of the second electrode 20 in the second direction is, for example, equal to the width (w3 in FIG. 41C) of the switching layer 40, which is provided between the first layer 70a and the second layer 70b, in the second direction.

A part of the second contact region 21 is provided between the first layer 70a and the second electrode 20 in the first direction. A part of the second contact region 21 is in contact with the first layer 70a and the second electrode 20.

Another part of the second contact region 21 is provided between the second layer 70b and the second electrode 20 in the first direction. Another part of the second contact region 21 is in contact with the second layer 70b and the second electrode 20.

As described above, according to the sixth embodiment, the first other embodiment of the sixth embodiment, and the second other embodiment of the sixth embodiment, as in the first embodiment, it is possible to realize a switching element in which film peeling between the first electrode 10 and the switching layer 40 and film peeling between the second electrode 20 and the switching layer 40 are suppressed. Therefore, it is possible to realize a memory device with excellent characteristics.

### Seventh Embodiment

A memory device according to a seventh embodiment is different from the memory device according to the sixth embodiment in that a part of the switching layer is provided in a first direction of the first layer and another part of the switching layer is provided in the first direction of the second layer. Hereinafter, the description of a part of the content overlapping the first or sixth embodiment will be omitted.

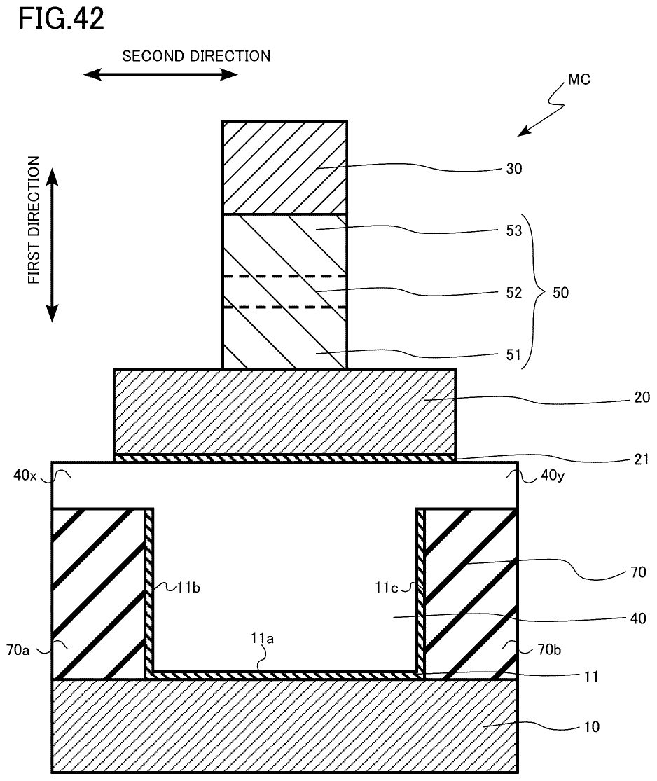

FIG. 42 is a schematic cross-sectional view of a memory cell of the memory device according to the seventh embodiment. FIG. 42 shows a cross section of one memory cell MC indicated by, for example, a dotted circle in the memory cell array 100 of FIG. 1.

As shown in FIG. 42, the memory cell MC includes a first electrode 10, a second electrode 20, a third electrode 30, a switching layer 40, a variable resistance layer 50, and an interlayer insulating layer 70. In addition, as shown in FIG. 42, the memory cell MC includes a first contact region 11 and a second contact region 21.

The first contact region 11 includes a first sub-region 11a, a second sub-region 11b, and a third sub-region 11c. The interlayer insulating layer 70 includes a first layer 70a and a second layer 70b.

A part 40x of the switching layer 40 is provided in the first direction of the first layer 70a. The part 40x of the switching layer 40 is provided on the first layer 70a. The part 40x of the switching layer 40 is in contact with, for example, the first layer 70a.

Another part 40y of the switching layer 40 is provided in the first direction of the second layer 70b. Another part 40y of the switching layer 40 is provided on the second layer 70b. Another part 40y of the switching layer 40 is in contact with, for example, the second layer 70b.

As described above, according to the seventh embodiment, as in the first embodiment, it is possible to realize a switching element in which film peeling between the first electrode 10 and the switching layer 40 and film peeling between the second electrode 20 and the switching layer 40 are suppressed. Therefore, it is possible to realize a memory device with excellent characteristics.

### Eighth Embodiment

A memory device according to an eighth embodiment is different from the memory device according to the third embodiment in that the memory device according to the eighth embodiment further includes an insulating layer including a first layer and a second layer, a switching layer is provided between the first layer and the second layer in a second direction perpendicular to a first direction from a first electrode to a second electrode, the switching layer including a first portion facing the first electrode, a second portion facing the first layer, and a third portion facing the second layer, and at least a part of the second electrode is provided between the second portion and the third portion in the second direction. Hereinafter, the description of a part of the content overlapping the third embodiment may be omitted.

The memory device according to the eighth embodiment is different from the memory device according to the fourth embodiment in that the memory cell does not include the third electrode and the variable resistance layer and includes a structure similar to the switching layer in the fourth embodiment as a memory layer. Hereinafter, the description of a part of the content overlapping the fourth embodiment will be omitted.

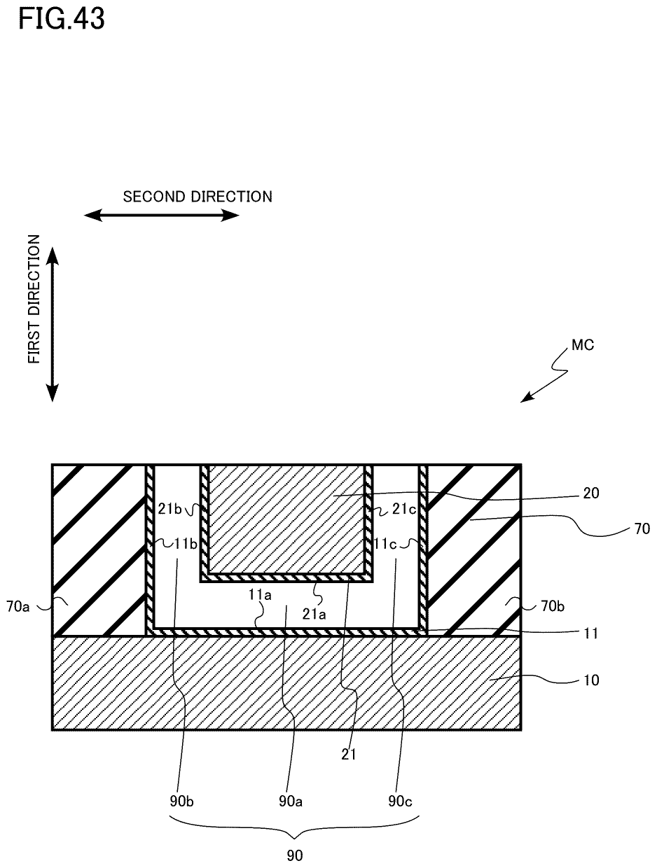

FIG. 43 is a schematic cross-sectional view of a memory cell of the memory device according to the eighth embodiment. FIG. 43 shows a cross section of one memory cell MC indicated by, for example, a dotted circle in the memory cell array 100 of FIG. 1.

As shown in FIG. 43, the memory cell MC includes a first electrode 10, a second electrode 20, a memory layer 90, and an interlayer insulating layer 70. In addition, as shown in FIG. 43, the memory cell MC includes a first contact region 11 and a second contact region 21.

The memory layer 90 includes a first portion 90a, a second portion 90b, and a third portion 90c. The first contact region 11 includes a first sub-region 11a, a second sub-region 11b, and a third sub-region 11c. The second contact region 21 includes a fourth sub-region 21a, a fifth sub-region 21b, and a sixth sub-region 21c. The interlayer insulating layer 70 includes a first layer 70a and a second layer 70b.

The interlayer insulating layer 70 is an example of an insulating layer. The first contact region 11 is an example of a region. The second contact region 21 is an example of a region.

The first contact region 11 is an example of a region. The second contact region 21 is an example of a region.

The first electrode 10, the memory layer 90, the second electrode 20, the first contact region 11, and the second contact region 21 form a memory element of the memory cell MC. The memory element of the memory cell MC has a switching function and an information storage function.

The memory layer 90 has the same configuration as the switching layer 40 in the fourth embodiment.

The memory layer 90 is provided between the first electrode 10 and the second electrode 20 in the first direction. The memory layer 90 is provided between the first layer 70a and the second layer 70b in the second direction.

The first portion 90a of the memory layer 90 faces the first electrode 10. The first portion 90a is provided between the first electrode 10 and the second electrode 20 in the first direction.

The second portion 90b of the memory layer 90 faces the first layer 70a. The second portion 90b is provided between the first layer 70a and the second electrode 20 in the second direction.

The third portion 90c of the memory layer 90 faces the second layer 70b. The third portion 90c is provided between the second layer 70b and the second electrode 20 in the second direction.

The first contact region 11 includes a first sub-region 11a, a second sub-region 11b, and a third sub-region 11c.

The first sub-region 11a is provided between the first electrode 10 and the first portion 90a in the first direction. The first sub-region 11a is in contact with, for example, the first electrode 10 and the first portion 90a.

The second sub-region 11b is provided between the first layer 70a and the second portion 90b in the second direction. The second sub-region 11b is in contact with, for example, the first layer 70a and the second portion 90b.

The third sub-region 11c is provided between the second layer 70b and the third portion 90c in the second direction. The third sub-region 11c is in contact with, for example, the second layer 70b and the third portion 90c.

The second contact region 21 includes a fourth sub-region 21a, a fifth sub-region 21b, and a sixth sub-region 21c.

The fourth sub-region 21a is provided between the first portion 90a and the second electrode 20 in the first direction. The fourth sub-region 21a is in contact with, for example, the first portion 90a and the second electrode 20.

The fifth sub-region 21b is provided between the second portion 90b and the second electrode 20 in the second direction. The fifth sub-region 21b is in contact with, for example, the second portion 90b and the second electrode 20.

The sixth sub-region 21c is provided between the third portion 90c and the second electrode 20 in the second direction. The sixth sub-region 21c is in contact with, for example, the third portion 90c and the second electrode 20.

The memory layer 90 has a nonlinear current-voltage characteristic that a current increases abruptly at a specific threshold voltage. In addition, the memory layer 90 has a characteristic that the threshold voltage changes with the application of a predetermined voltage. The memory layer 90 has a characteristic that the electrical resistance changes with the application of a predetermined voltage. In the eighth embodiment, the high resistance state is a state in which the resistance of the memory layer 90 is relatively high at the read voltage. In addition, in the eighth embodiment, the low resistance state is a state in which the resistance of the memory layer 90 is relatively low at the read voltage.

The memory layer 90 has a function of suppressing an increase in half-select leakage current flowing through the half-selected cell. In addition, the memory layer 90 has a function of storing data by resistance change. The memory layer 90 is a single layer, and realizes the function of the switching layer 40 and the function of the variable resistance layer 50 in the fourth embodiment.

In the memory device according to the eighth embodiment, the memory element of the memory cell MC has a switching function and an information storage function. The memory layer 90 is a single layer, and realizes the function of the switching layer 40 and the function of the variable resistance layer 50 in the fourth embodiment. Since the memory layer 90 in the eighth embodiment is a single layer and has a switching function and a memory function, the structure of the memory cell MC can be made very simple.

In addition, the first electrode 10, the second electrode 20, the first contact region 11, and the second contact region 21 of the memory device according to the eighth embodiment have the same configuration as the first electrode 10, the second electrode 20, the first contact region 11, and the second contact region 21 in the fourth embodiment. Therefore, according to the eighth embodiment, it is possible to realize a memory device having excellent characteristics, as in the fourth embodiment.

Although the magnetoresistive memory has been described as an example of the two-terminal memory device in the first, fourth, fifth, sixth, and seventh embodiments and the resistive random access memory has been described as an example of the memory device in the second embodiment, embodiments can be applied to other two-terminal memory devices. For example, embodiments can be applied to a phase change memory (PCM) or a ferroelectric random access memory (FeRAM).

In the eighth embodiment, a case where a structure similar to the switching layer in the fourth embodiment is included as a memory layer has been described as an example, but it is also possible to adopt a configuration in which a structure similar to the switching layer in the fifth to seventh embodiments is included as a memory layer.

Parts of the switching layers (selectors) described in each of the above-described embodiments and its modification examples may have a crystalline material, and for example, the crystalline material is not limited to an oxide. In addition, for example, it is desirable that ZnTe is crystallized in the switching layer, but ZnTe does not have to be crystallized.

While certain embodiments have been described, these embodiments have been presented by way of example only, and are not intended to limit the scope of the inventions. Indeed, the memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A memory device, comprising:
a memory cell including a first electrode, a second electrode, a third electrode, a switching layer, a variable resistance layer, and a region,
wherein the second electrode is provided between the first electrode and the third electrode,
the switching layer is provided between the first electrode and the second electrode,
the variable resistance layer is provided between the second electrode and the third electrode,
wherein the switching layer contains:
an oxide or oxynitride of a first element being at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg);
a second element being different from the first element, and being at least one element selected from a group consisting of aluminum (Al), zinc (Zn), tin (Sn), gallium (Ga), bismuth (Bi), and indium (In); and
a third element being at least one element selected from a group consisting of tellurium (Te), sulfur (S), selenium (Se), and antimony (Sb),
wherein at least one electrode of the first electrode and the second electrode contains carbon (C), and
the region is provided between at least one of the at least one electrode and the switching layer, the region containing a fourth element, the fourth element being different from the first element, the second element, and the third element, and the fourth element being at least one element selected from a group consisting of titanium (Ti), tungsten (W), molybdenum (Mo), tantalum (Ta), aluminum (Al), boron (B), chromium (Cr), hafnium (Hf), niobium (Nb), vanadium (V), silicon (Si), and zirconium (Zr).

2. The memory device according to claim 1,
wherein the region contains a fifth element, the fifth element being at least one element of nitrogen (N) and carbon (C).

3. The memory device according to claim 1,
wherein the region contains a sixth element, the sixth element being at least one element selected from a group consisting of zinc (Zn), gallium (Ga), germanium (Ge), tellurium (Te), lanthanum (La), and cerium (Ce).

4. The memory device according to claim 1,
wherein the region contains at least one element selected from a group consisting of the first element, the second element, and the third element.

5. The memory device according to claim 1,
wherein the region has a layer shape.

6. The memory device according to claim 1,
wherein the region has a plurality of portions spaced from each other along a face where the switching layer faces the at least one of the at least one electrode.

7. The memory device according to claim 1,
wherein a thickness of the region in a first direction from the first electrode to the second electrode is equal to or less than 5 nm.

8. The memory device according to claim 1,
wherein a thickness of the region in a first direction from the first electrode to the second electrode is smaller than a thickness of the first electrode in the first direction and a thickness of the second electrode in the first direction.

9. The memory device according to claim 1,
wherein the region is provided between the at least one electrode and the switching layer.

10. The memory device according to claim 1,
wherein the first electrode and the second electrode contain carbon (C), and the region is provided between the first electrode and the switching layer and between the second electrode and the switching layer.

11. The memory device according to claim 1,
wherein the at least one of the first electrode and the second electrode includes a carbon layer, and the carbon layer is in contact with the region.

12. The memory device according to claim 1,
wherein the region is in contact with the switching layer.

13. The memory device according to claim 1,
wherein the switching layer contains a compound of the second element and the third element.

14. The memory device according to claim 1,
wherein the variable resistance layer includes a magnetic tunnel junction.

15. The memory device according to claim 1,
wherein the variable resistance layer has an electrical resistance changing with application of a predetermined voltage, and
the switching layer has a nonlinear current-voltage characteristic that a current increases at a specific threshold voltage.

16. The memory device according to claim 1, further comprising:
a plurality of first wirings; and
a plurality of second wirings crossing the plurality of first wirings,
wherein the memory cell is provided in a portion where one of the plurality of first wirings crosses one of the plurality of second wirings.

17. The memory device according to claim 1, further comprising:
an insulating layer including a first layer and a second layer,
wherein the switching layer is provided between the first layer and the second layer in a second direction perpendicular to a first direction from the first electrode to the second electrode,
the switching layer includes a first portion facing the first electrode, a second portion facing the first layer, and a third portion facing the second layer, and
at least a part of the second electrode is provided between the second portion and the third portion in the second direction.

18. The memory device according to claim 17,
wherein the first electrode contains carbon (C),
the region is provided between the first electrode and the switching layer,
the region includes a first sub-region, a second sub-region, and a third sub-region, and
the first sub-region is provided between the first electrode and the first portion, the second sub-region is provided between the first layer and the second portion, and the third sub-region is provided between the second layer and the third portion.

19. The memory device according to claim 17,
wherein the second electrode contains carbon (C),
the region is provided between the second electrode and the switching layer,
the region includes a fourth sub-region, a fifth sub-region, and a sixth sub-region, and
the fourth sub-region is provided between the first portion and the second electrode, the fifth sub-region is provided between the second portion and the second electrode, and the sixth sub-region is provided between the third portion and the second electrode.

20. The memory device according to claim 17,
wherein a part of the switching layer is provided in the first direction of the first layer, and
another part of the switching layer is provided in the first direction of the second layer.

21. The memory device according to claim 20,
wherein the part of the switching layer is in contact with the first layer, and
the another part of the switching layer is in contact with the second layer.

22. The memory device according to claim 17,
wherein a width of the variable resistance layer in the second direction is equal to or smaller than a width of the second electrode in the second direction.

23. The memory device according to claim 1, further comprising:
an insulating layer including a first layer and a second layer,
wherein the switching layer is provided between the first layer and the second layer in a second direction perpendicular to a first direction from the first electrode to the second electrode, and
a width of the second electrode in the second direction is larger than a width of the switching layer between the first layer and the second layer in the second direction.

24. The memory device according to claim 23,
wherein a part of the switching layer is provided in the first direction of the first layer, and
another part of the switching layer is provided in the first direction of the second layer.

25. The memory device according to claim 24,
wherein the part of the switching layer is in contact with the first layer, and
the another part of the switching layer is in contact with the second layer.

26. A memory device, comprising:
a memory cell including a first electrode, a second electrode, a memory layer provided between the first electrode and the second electrode, and a region,
wherein the memory layer contains:
an oxide or oxynitride of a first element being at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg);
a second element being different from the first element, and being at least one element selected from a group consisting of aluminum (Al), zinc (Zn), tin (Sn), gallium (Ga), bismuth (Bi), and indium (In); and
a third element being at least one element selected from a group consisting of tellurium (Te), sulfur (S), selenium (Se), and antimony (Sb),
wherein at least one electrode of the first electrode and the second electrode contains carbon (C), and
the region is provided between at least one of the at least one electrode and the memory layer, the region containing a fourth element, the fourth element being different from the first element, the second element, and the third element, and the fourth element being at least one element selected from a group consisting of titanium (Ti), tungsten (W), molybdenum (Mo), tantalum (Ta), aluminum (Al), boron (B), chromium (Cr), hafnium (Hf), niobium (Nb), vanadium (V), silicon (Si), and zirconium (Zr).

27. The memory device according to claim 26,
wherein the region contains a fifth element, the fifth element being at least one element of nitrogen (N) and carbon (C).

28. The memory device according to claim 26,
wherein the region contains a sixth element, the sixth element being at least one element selected from a group consisting of zinc (Zn), gallium (Ga), germanium (Ge), tellurium (Te), lanthanum (La), and cerium (Ce).

29. The memory device according to claim 26,
wherein the region contains at least one element selected from a group consisting of the first element, the second element, and the third element.

30. The memory device according to claim 26,
wherein the memory layer has a nonlinear current-voltage characteristic that a current increases at a specific threshold voltage, and the threshold voltage changes with application of a predetermined voltage.

31. The memory device according to claim 26, further comprising:
a plurality of first wirings; and
a plurality of second wirings crossing the plurality of first wirings,
wherein the memory cell is provided in a portion where one of the plurality of first wirings and one of the plurality of second wirings cross each other.

32. The memory device according to claim 26, further comprising:
an insulating layer including a first layer and a second layer,
wherein the memory layer is provided between the first layer and the second layer in a second direction perpendicular to a first direction from the first electrode to the second electrode,
the memory layer includes a first portion facing the first electrode, a second portion facing the first layer, and a third portion facing the second layer, and
at least a part of the second electrode is provided between the second portion and the third portion in the second direction.

33. The memory device according to claim 32,
wherein the first electrode contains carbon (C),
the region is provided between the first electrode and the memory layer,
the region includes a first sub-region, a second sub-region, and a third sub-region, and
the first sub-region is provided between the first electrode and the first portion, the second sub-region is provided between the first layer and the second portion, and the third sub-region is provided between the second layer and the third portion.

34. The memory device according to claim 32,
wherein the second electrode contains carbon (C),
the region is provided between the second electrode and the memory layer,
the region includes a fourth sub-region, a fifth sub-region, and a sixth sub-region, and
the fourth sub-region is provided between the first portion and the second electrode, the fifth sub-region is provided between the second portion and the second electrode, and the sixth sub-region is provided between the third portion and the second electrode.

35. The memory device according to claim 26, further comprising:
an insulating layer including a first layer and a second layer,
wherein the memory layer is provided between the first layer and the second layer in a second direction perpendicular to a first direction from the first electrode to the second electrode, and
a width of the second electrode in the second direction is larger than a width of the memory layer between the first layer and the second layer in the second direction.
